(19) United States
(12) Patent Application Publication
(10) Pub. No.: US 2026/0156770 A1
(43) Pub. Date: Jun. 4, 2026

(54) ELECTRONIC DEVICE

(71) Applicant: CANAAN CREATIVE CO., LTD., Beijing (CN)

(72) Inventors: Shaohua ZHANG, Beijing (CN); Nangeng ZHANG, Beijing (CN)

(21) Appl. No.: 19/122,253

(22) PCT Filed: Oct. 20, 2023
(86) PCT No.: PCT/CN2023/125711

§ 371 Date: Apr. 17, 2025

(30) Foreign Application Priority Data
Oct. 20, 2022 (CN) 202211287134.7
May 12, 2023 (CN) 202310540092.1

(51) Int. Cl. H05K 7/20; G06F 1/26

(52) U.S. Cl. CPC H05K 7/20145; G06F 1/263

(57) ABSTRACT

An electronic device. The electronic device comprises: a housing, wherein a heat-dissipating air duct with an air inlet and an air outlet is defined within the housing, and at least one working assembly is disposed in the heat-dissipating air duct; and a power supply module configured to supply power to the working assembly, wherein the power supply module is disposed on a side surface of the housing, and the power supply module is disposed to keep clear of the air inlet and the air outlet. It may enable more convenient installation and disassembly of the working assembly and can effectively improve the efficiency of servicing and replacement of the working assembly.

### CROSS REFERENCE TO RELATED APPLICATIONS

This present application is a U.S. National Stage Application of International Application No. PCT/CN2023/125711, filed on Oct. 20, 2023, which claims priority to and benefits of Chinese Patent Application No. 202211287134.7, titled “ELECTRONIC DEVICE”, filed with the China National Intellectual Property Administration on Oct. 20, 2022, and Chinese Patent Application No. 202310540092.1, titled “ELECTRONIC DEVICE”, filed with the China National Intellectual Property Administration on May 12, 2023. The entire contents of all of the above-identified applications are incorporated herein by reference.

### TECHNICAL FIELD

The present application relates to the field of heat dissipation technology, and in particular to an electronic device.

### BACKGROUND

In the related art, a computing device is usually provided with a plurality of working assemblies.

### SUMMARY

Embodiments of the present application provide an electronic device.

As one aspect of the embodiments of the application, the present application provides in its embodiments an electronic device. The electronic device comprises: a housing, wherein a heat-dissipating air duct with an air inlet and an air outlet is defined within the housing, and at least one working assembly is disposed in the heat-dissipating air duct; and a power supply module configured to supply power to the working assembly, wherein the power supply module is disposed on a side surface of the housing, and the power supply module is disposed to keep clear of the air inlet and the air outlet.

In one implementation, the housing comprises a first housing side surface and a second housing side surface that are disposed opposite to each other, as well as a third housing side surface and a fourth housing side surface that are disposed opposite to each other, the air inlet and the air outlet are respectively disposed on the first housing side surface and the second housing side surface, and the power supply module is disposed on the third housing side surface and/or the fourth housing side surface.

In one implementation, the power supply module comprises a first power supply side surface and a second power supply side surface that are disposed opposite to each other, as well as a third power supply side surface and a fourth power supply side surface that are disposed opposite to each other, wherein the first power supply side surface is coplanar with the first housing side surface, the second power supply side surface is coplanar with the second housing side surface, and the third power supply side surface is coplanar with the fourth housing side surface.

In one implementation, a top surface of the power supply module is coplanar with a top surface of the housing.

In one implementation, a bottom surface of the power supply module is coplanar with a bottom surface of the housing.

In one implementation, the electronic device further comprises: a top housing disposed on the top of the housing and the power supply module.

In one implementation, the top housing comprises a first top housing side surface and a second top housing side surface that are disposed opposite to each other, as well as a third top housing side surface and a fourth top housing side surface that are disposed opposite to each other, wherein the first top housing side surface is coplanar with the air inlet, and the second top housing side surface is coplanar with the air outlet.

In one implementation, the fourth top housing side surface is coplanar with a side surface of the power supply module, and a side surface of the housing facing away from the power supply module is coplanar with the third top housing side surface.

In one implementation, at least one first positioning portion is provided on one of the power supply module and the top housing, and at least one second positioning portion is provided on the other of the power supply module and the top housing, and the first positioning portion mates with the second positioning portion.

In one implementation, the first positioning portion is a positioning hole, the second positioning portion is a positioning protrusion, and the positioning protrusion is fitted into the corresponding positioning hole.

In one implementation, at least one first connection portion is formed on one of the power supply module and the housing, and at least one second connection portion corresponding to the first connection portion is formed on the other of the power supply module and the housing, and a fastener passes through the first connection portion to be connected to the second connection portion.

In one implementation, the first connection portion is a through hole, the second connection portion is a threaded hole, and the fastener is a threaded fastener.

In one implementation, the electronic device further comprises: a conductive connection member, one part of which is electrically connected to the power supply module, and the other part of which is electrically connected to the working assembly.

In one implementation, the conductive connection member comprises: a first conductive connection member, one part of which is electrically connected to the power supply module, and the other part of which is electrically connected to a first connection base of the working assembly; and a second conductive connection member, one part of which is electrically connected to the power supply module, and the other part of which is electrically connected to a second connection base of the working assembly.

In one implementation, the first connection base and/or the second connection base is provided with an opening for positioning during installation and gas venting during welding.

In one implementation, the other part of the first conductive connection member and the other part of the second conductive connection member both extend in a direction that is perpendicular to a direction from the air inlet to the air outlet and perpendicular to a vertical direction.

In one implementation, the electronic device further comprises: a fan assembly arranged on a side of the housing close to the air inlet.

In one implementation, the electronic device further comprises: a fan assembly arranged on a side of the housing close to the air outlet.

In one implementation, the electronic device further comprises: a fan assembly; the fan assembly includes: a mounting member connected to a housing; and a fan module connected to a side of the mounting member facing away from the housing.

In one implementation, the fan assembly includes two fan modules arranged in a vertical direction.

In one implementation, the two fan modules arranged in the vertical direction constitute a fan group, and there are a plurality of fan groups disposed in a direction from the air inlet to the air outlet.

In one implementation, first mounting portions are provided at four corners of the fan module, second mounting portions are provided on the mounting member, and fasteners respectively pass through the first mounting portions to be connected to corresponding second mounting portions.

In one implementation, the first mounting portions are through holes, the second mounting portions are threaded holes, and the fasteners are threaded fasteners.

In one implementation, a flexible protective cover is provided on a side of the fan module facing away from the mounting member, and the flexible protective cover is sleeved on an outer periphery of the fan module.

In one implementation, the fan assembly and the working assembly are disposed to be spaced apart from each other in a direction from the air inlet to the air outlet.

The above summary is for the purpose of illustration only and is not intended to be limiting in any way. In addition to the schematic aspects, implementations and features described above, further aspects, implementations and features of the present application will readily apparent by referring to the accompanying drawings and the following detailed description.

### BRIEF DESCRIPTION OF THE DRAWINGS

In the drawings, unless otherwise specified, the same reference numerals refer to the same or similar parts or elements throughout the drawings. The drawings are not necessarily drawn to scale. It should be understood that these drawings only depict some implementations disclosed in accordance with the present application and should not be considered as limiting the scope of the present application.

FIG. 1 is a schematic perspective structural diagram of an electronic device according to an embodiment of the present application;

FIG. 2 is a perspective view of the electronic device shown in FIG. 1 from another perspective;

FIG. 3 is a front view of the electronic device shown in FIG. 1;

FIG. 4 is a rear view of the electronic device shown in FIG. 1;

FIG. 5 is a left view of the electronic device shown in FIG. 1;

FIG. 6 is a right view of the electronic device shown in FIG. 1;

FIG. 7 is a top view of the electronic device shown in FIG. 1;

FIG. 8 is a bottom view of the electronic device shown in FIG. 1;

FIG. 9A is an exploded view of the electronic device shown in FIG. 1;

FIG. 9B is an enlarged view of the circled portion A in FIG. 9A;

FIG. 10A is a schematic structural diagram of a ventilation panel according to another embodiment of the present application;

FIG. 10B is a partial enlarged view of the ventilation panel shown in FIG. 10A;

FIG. 11 is another exploded view of the electronic device shown in FIG. 1;

FIG. 12 is a schematic diagram of installing a fan assembly of the electronic device shown in FIG. 1;

FIG. 13 is a sectional view of the electronic device shown in FIG. 1;

FIG. 14 is a schematic diagram of cable connection of a fan module of the electronic device shown in FIG. 1;

FIG. 15 is a perspective view of a fan assembly of the electronic device shown in FIG. 1;

FIG. 16 is an enlarged view of the circled portion B in FIG. 15;

FIG. 17 is a perspective view of a fan assembly of the electronic device shown in FIG. 1 from another perspective;

FIG. 18 is a perspective view of a mounting member of the fan assembly shown in FIG. 17;

FIG. 19 is a perspective view of a flexible protective cover of the fan assembly shown in FIG. 17;

FIG. 20 is a schematic diagram of the internal structure of the electronic device shown in FIG. 1;

FIG. 21 is a schematic diagram of cable connection of the electronic device shown in FIG. 1;

FIG. 22 is a schematic structural diagram of a first conductive connection member and a second conductive connection member according to an embodiment of the present application;

FIG. 23 is a sectional view of an electronic device according to an embodiment of the present application;

FIG. 24 is an enlarged view of the circled portion C in FIG. 23;

FIG. 25A is a sectional view of an electronic device according to an embodiment of the present application;

FIG. 25B is an enlarged view of the circled portion D in FIG. 25A;

FIG. 26A is a sectional view of an electronic device according to an embodiment of the present application;

FIG. 26B is a partial enlarged view of the electronic device shown in FIG. 26A;

FIG. 27 is a schematic installation diagram of a power supply module according to an embodiment of the present application;

FIG. 28 is a schematic installation diagram of a power supply module from another perspective according to an embodiment of the present application;

FIG. 29A is a schematic diagram of the connection between a power supply module and a housing according to an embodiment of the present application;

FIG. 29B is an enlarged view of the circled portion E in FIG. 29A;

FIG. 30A is a schematic installation diagram of a power supply module of an electronic device according to another embodiment of the present application;

FIG. 30B is a partial enlarged view of the electronic device shown in FIG. 30A;

FIG. 30C is a schematic structural diagram of a threaded fastener of the electronic device shown in FIG. 30A;

FIG. 31 is a schematic perspective structural diagram of a working assembly according to an embodiment of the present application;

FIG. 32 is a perspective view of the working assembly shown in FIG. 31 from another perspective;

FIG. 33 is a front view of the working assembly shown in FIG. 31;

FIG. 34 is a rear view of the working assembly shown in FIG. 31;

FIG. 35 is a left view of the working assembly shown in FIG. 31;

FIG. 36 is a right view of the working assembly shown in FIG. 31;

FIG. 37 is a top view of the working assembly shown in FIG. 31;

FIG. 38 is a bottom view of the working assembly shown in FIG. 31; and

FIG. 39A is an exploded view of the working assembly shown in FIG. 31;

FIG. 39B is a schematic diagram of a working assembly according to another embodiment of the present application;

FIG. 40 is a schematic structural diagram of a first connection base of a working assembly according to an embodiment of the present application;

FIG. 41 is a schematic structural diagram of a first connection base of a working assembly according to an embodiment of the present application;

FIG. 42 is a schematic partial structural diagram of a sealing member of a working assembly according to an embodiment of the present application;

FIG. 43 is a schematic mounting diagram of a sealing member of a working assembly according to an embodiment of the present application;

FIG. 44 is a schematic structural diagram of a spring screw of a working assembly according to an embodiment of the present application;

FIG. 45 is a schematic perspective structural diagram of a working assembly according to another embodiment of the present application;

FIG. 46 is a front view of the working assembly shown in FIG. 45;

FIG. 47 is a rear view of the working assembly shown in FIG. 45;

FIG. 48 is a left view of the working assembly shown in FIG. 45;

FIG. 49 is a right view of the working assembly shown in FIG. 45;

FIG. 50 is a top view of the working assembly shown in FIG. 45;

FIG. 51 is a bottom view of the working assembly shown in FIG. 45; and

FIG. 52 is a schematic structural diagram of a circuit board according to an embodiment of the present application.

### NOTES OF REFERENCE NUMERALS

100: working assembly;
110: circuit board; 111: heat-generating component; 112: first signal socket; 120: heat sink; 121: heat sink body; 122: heat sink fin; 1221: beveled portion; 1222: groove; 123: first heat sink; 124: second heat sink; 140: first connection base; 141: connection body; 1411: flanging; 142: extension portion; 143: avoidance slot; 150: second connection base; 160: sealing member; 161: first sealing portion; 162: second sealing portion; 170: spring screw; 171: spring; 172: screw;
200: Electronic Device;
210: housing; 211: ventilation hole; 212: top housing; 2121: first top housing side surface; 2122: second top housing side surface; 2123: third top housing side surface; 2124: fourth top housing side surface; 213: ventilation panel; 2131: ventilation body; 2132: ventilation side plate; 2133: ventilation top plate; 2134: ventilation bottom plate; 2135: second bent portion; 2136: spacing slot; 2137: second ventilation hole; 214: second elastic clip; 215: second conductive foam; 216: first housing side surface; 217: second housing side surface; 218: third housing side surface; 219: fourth housing side surface; 220: fan assembly; 221: mounting member; 2211: threaded hole; 2212: fixing hole; 2213: mounting body; 2214: mounting side plate; 2215: mounting top plate; 2216: mounting bottom plate; 2217: first bent portion; 2218: reinforcing rib; 2219: via hole; 2220: first ventilation hole; 221a: third ventilation hole; 222: fan module; 230: first elastic clip; 231: connection portion; 232: abutment portion; 240: first conductive foam; 250: flexible protective cover; 260: control board; 261: second signal socket; 262: fan interface; 263: temperature sensor; 264: indicator light; 270: power supply module; 271: positioning hole; 272: through hole; 273: threaded fastener; 274: first power supply side surface; 275: second power supply side surface; 276: fourth power supply side surface; 280: first conductive connection member; 290: second conductive connection member.

### DETAILED DESCRIPTION

Hereinafter, certain exemplary embodiments are described briefly. As those skilled in the art will recognize, the described embodiments may be modified in various different ways without departing from the spirit or scope of the present application. Accordingly, the drawings and description are to be regarded as illustrative in nature and not restrictive.

A computing device is usually provided with a plurality of working assemblies. In the case of servicing or replacing the working assemblies, the operation is relatively cumbersome, which reduces the efficiency of servicing and replacement of the working assemblies.

By adopting the technical solutions disclosed herein, the embodiments of the present application may enable more convenient installation and disassembly of the working assembly and can effectively improve the efficiency of servicing and replacement of the working assembly.

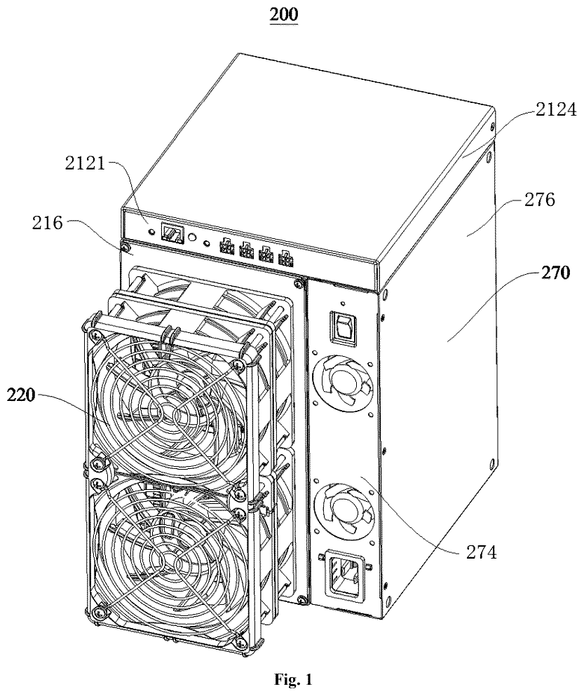

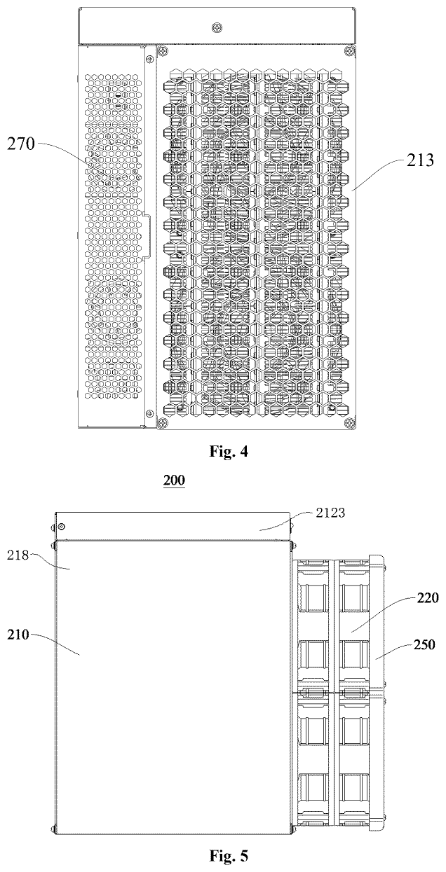

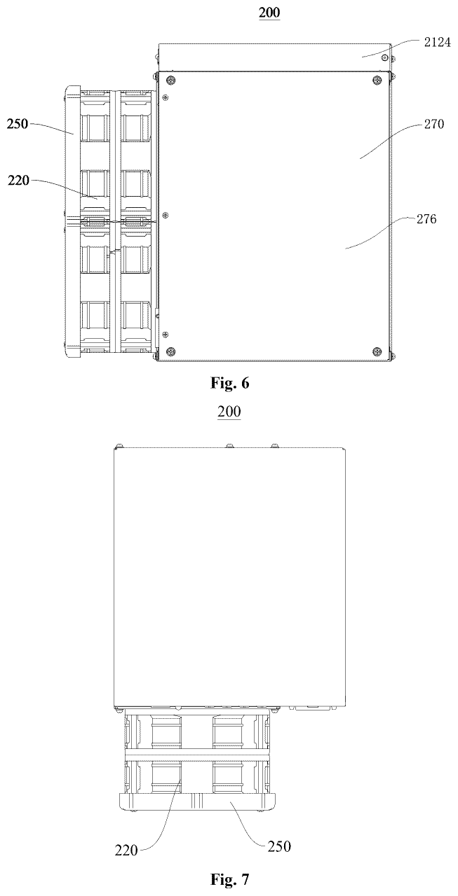

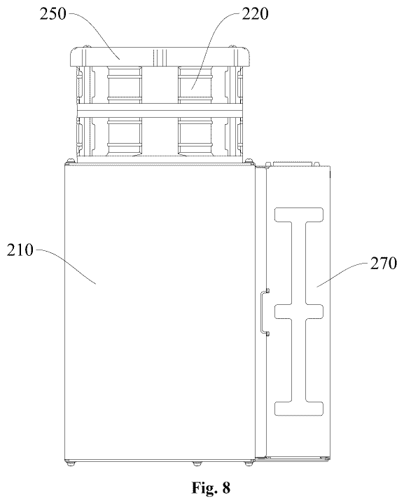

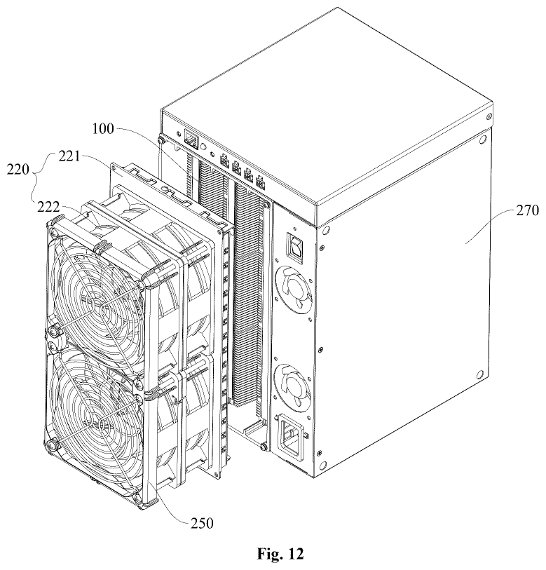

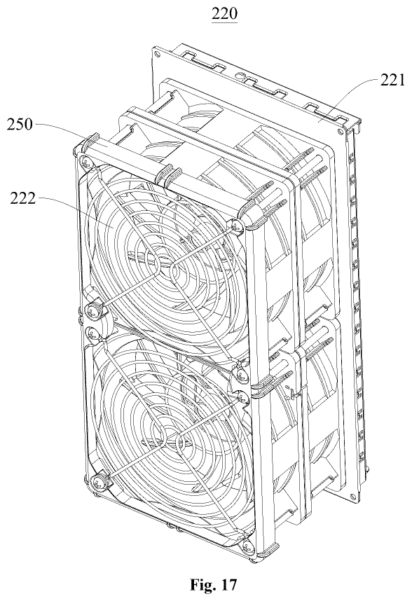

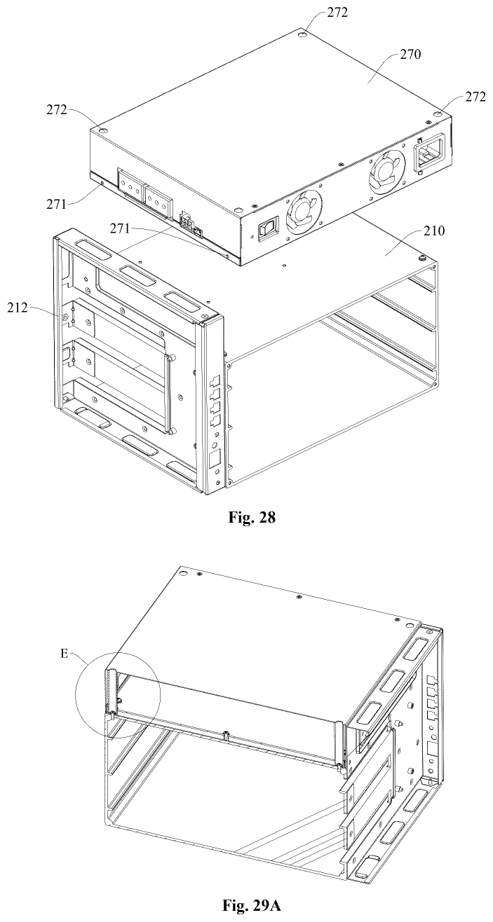

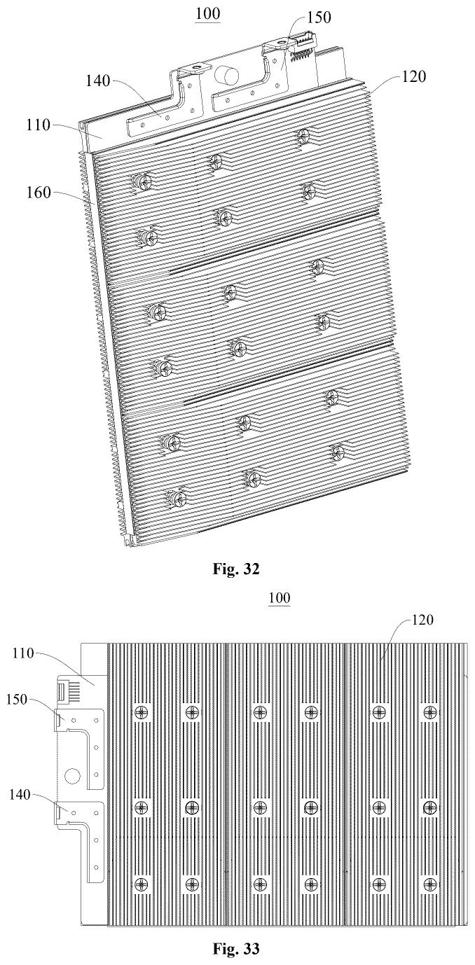

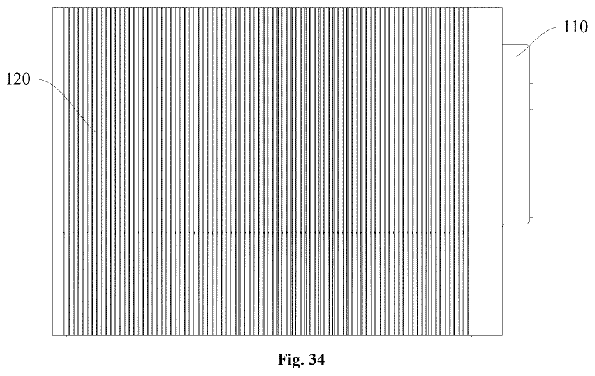

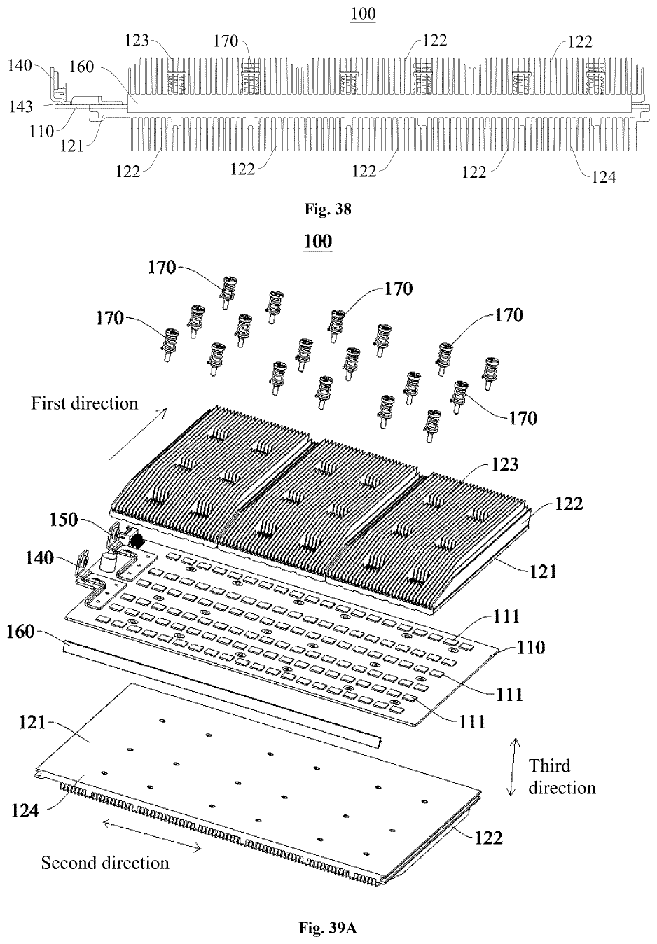

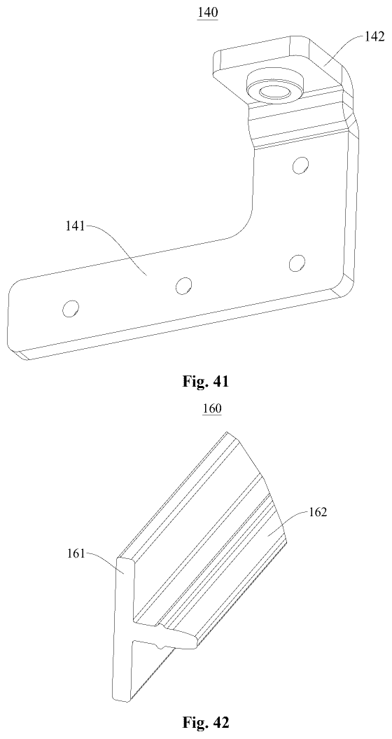

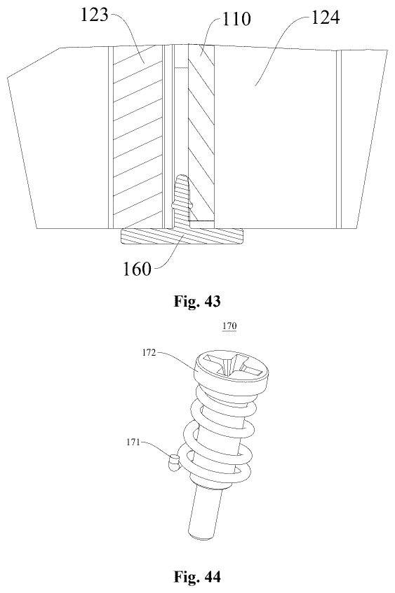

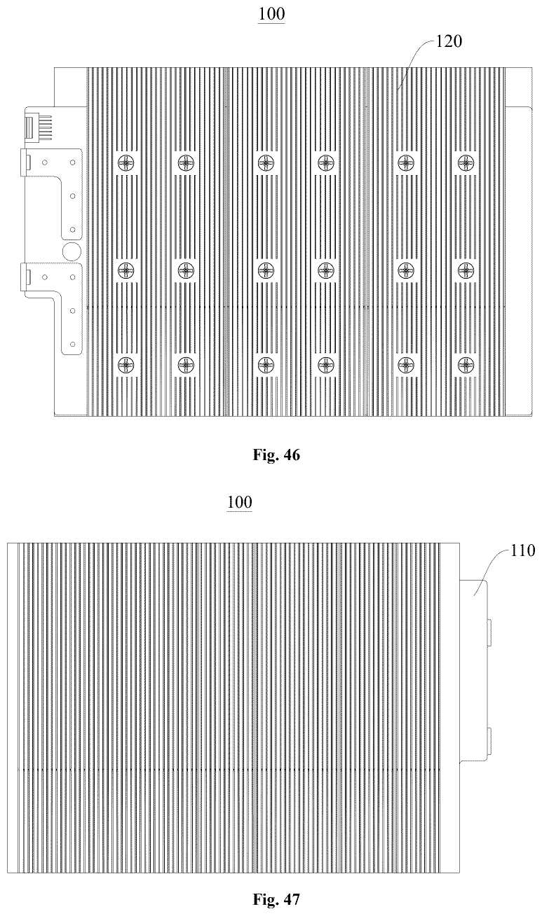

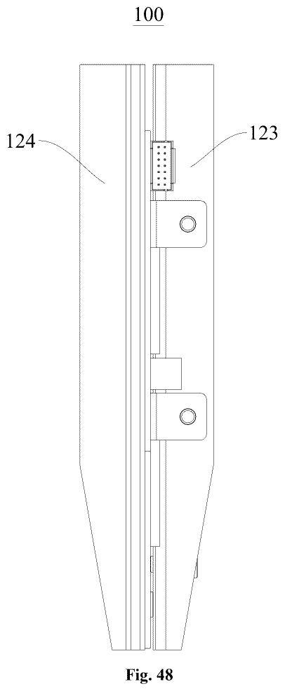

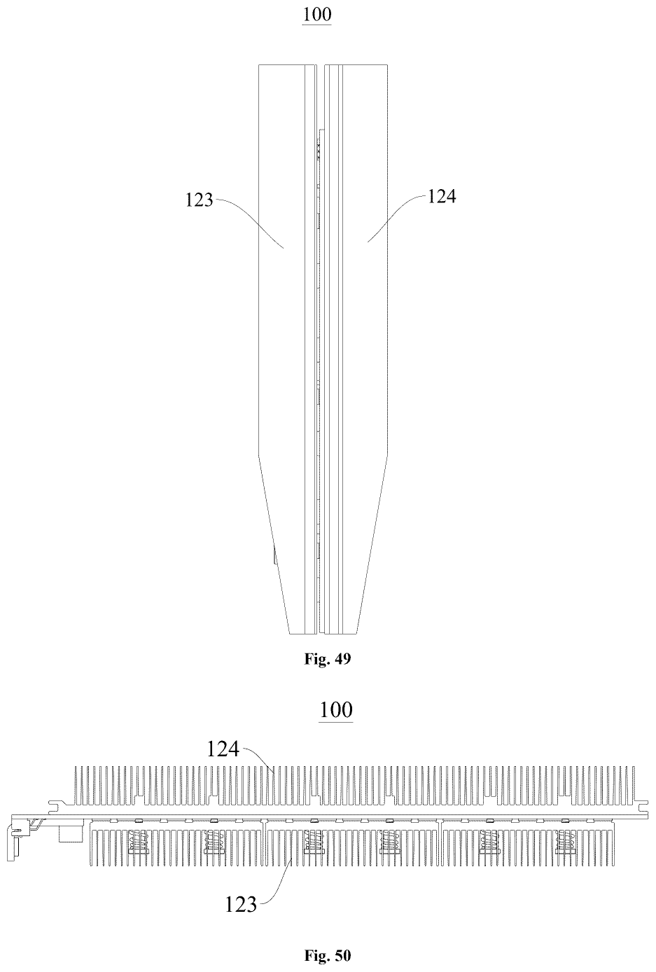

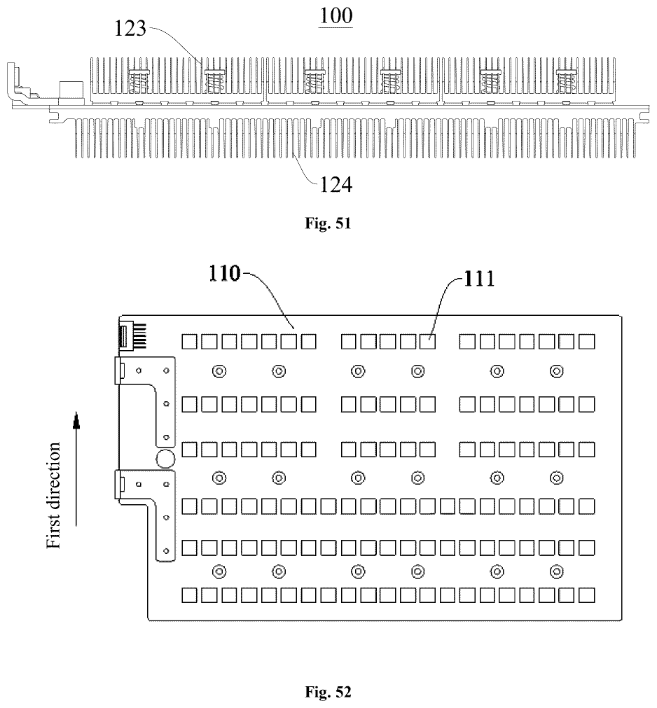

A working assembly 100 according to a first aspect of the embodiments of the present application is described below in conjunction with FIGS. 1-52. The working assembly 100 is suitable for working in a heat-dissipating air duct to achieve heat dissipation of the working assembly 100.

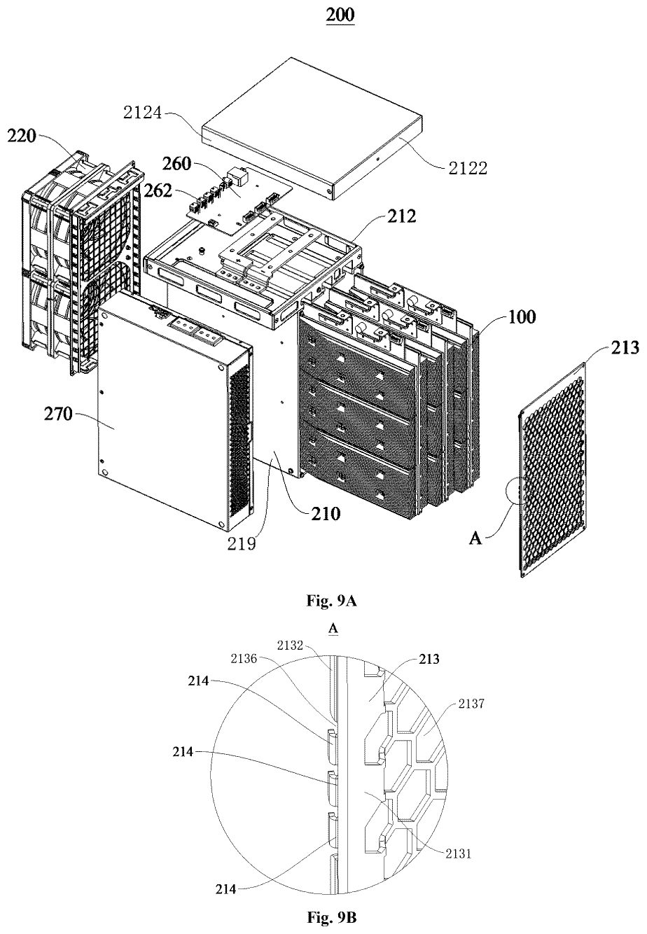

As shown in FIGS. 9 and 31-39A, the working assembly 100 includes a circuit board 110 and at least one heat sink 120. Specifically, a plurality of heat-generating components 111 are disposed on at least one side surface of the circuit board 110, and the heat sink 120 is disposed on the circuit board 110. In the description of the present application, “a plurality of” means two or more.

For example, two heat sinks 120 are shown in the examples of FIGS. 31-39A, and the two heat sinks 120 are respectively a first heat sink 123 and a second heat sink 124. The first heat sink 123 is disposed on a first surface of the circuit board 110, and the second heat sink 124 is disposed on a second surface of the circuit board 110. The plurality of heat-generating components 111 may include a plurality of chips disposed on the first surface of the circuit board 110, the first heat sink 123 may be disposed corresponding to the chips, and the first heat sink 123 may be in contact with the chips directly or indirectly through a thermally conductive material (such as silicone grease). The first heat sink 123 is provided with a plurality of bosses, which are disposed corresponding to the chips. The bosses may be disposed in a plurality of rows or columns, with each row of a plurality of rows of bosses corresponding to each row of chips; each column of a plurality of columns of bosses corresponding to each column of chips; the bosses may also be an array of independent structures, with each independent boss corresponding to a single chip, and the cross-sectional area of each independent boss may cover a single chip or be smaller than a single chip. The first heat sink 123 may include a plurality of independently disposed sub-heat sinks.

The heat on the first surface of the circuit board 110 can be effectively conducted to the first heat sink 123, and the heat on the second surface of the circuit board 110 can be effectively conducted to the second heat sink 124. In the process of air blowing from the air inlet to the air outlet of the heat-dissipating air duct, the heat of the first heat sink 123 and the second heat sink 124 can be effectively taken away, thereby achieving effective heat dissipation of the circuit board 110.

Although two heat sinks 120 are shown in FIGS. 31-39A for illustrative purposes, after reading the technical solution of the present application, a person of ordinary skill in the art will clearly understand that the solution may be applied to technical solutions involving one heat sink or more than two heat sinks 120, and such applications also fall within the scope of protection of the present application.

At the air outlet of the heat-dissipating air duct, the size of at least one heat sink 120 in the first direction is larger than the size of the circuit board 110 in the first direction, and the first direction is a direction from the air inlet to the air outlet of the heat-dissipating air duct. An edge of at least one heat sink 120 close to the air outlet exceeds an edge of the circuit board 110 close to the air outlet.

Illustratively, the first and second surfaces of the circuit board 110 may both be parallel to the first direction. The plurality of heat-generating components 111 on the first surface may be disposed in rows, and in the first direction, the centers of at least three or all of the heat-generating components 111 are in a straight line. The plurality of heat-generating components 111 on the first surface may be disposed in columns, and in the second direction, the centers of at least three or all of the heat-generating components 111 are in a straight line, and the second direction is perpendicular to the first direction. FIG. 39A shows six columns of heat-generating components 111. The six columns of heat-generating components 111 may be divided into two parts, and each part includes three columns of heat-generating components 111. One of the two parts is disposed close to the air inlet, and the other of the two parts is disposed close to the air outlet. The edges of the first heat sink 123 and the second heat sink 124 close to the air outlet may both extend beyond the edge of the circuit board 110 close to the air outlet. With such a configuration, it may increase the area of the heat sink 120 at the air outlet, so that the heat of a group of heat-generating components 111 close to the air outlet can be better conducted to the corresponding heat sink 120, reducing the maximum temperature difference between the three columns of heat-generating components 111 close to the air outlet. At the same time, the heat dissipation effect of the three columns of heat-generating components 111 close to the air outlet can be improved, which is beneficial to reducing the maximum temperature difference between the two groups of heat-generating components 111, thereby improving the overall temperature uniformity of the plurality of heat-generating components 111.

The working assembly 100 according to the embodiments of the present application may lengthen the size of the at least one heat sink 120 close to the air outlet in the first direction, thereby reducing the maximum temperature difference between the heat-generating components 111 close to the air outlet and the heat-generating components 111 close to the air inlet, thereby improving the temperature uniformity of the heat-generating components 111.

In one implementation, along the first direction, the size of the heat sink 120 exceeds the size of the circuit board 110 by 10 mm to 20 mm (inclusive). Specifically, for example, the size of the heat sink 120 exceeds the size of the circuit board 110 by L. When L is less than 10 mm, at the air outlet of the heat-dissipating air duct, the size of the heat sink 120 exceeding the circuit board 110 in the first direction is too small, resulting in poor heat dissipation effect of the heat-generating components 111 close to the air outlet, and the temperature uniformity of the heat-generating components 111 cannot be effectively improved; when L is greater than 20 mm, the size of the heat sink 120 exceeding the circuit board 110 in the first direction is too large, and the space occupied by the heat sink 120 at the air outlet is too large, which will increase the volume of the housing 210 and cause the weight of the heat sink 120 to be too heavy.

Therefore, by ensuring that 10 mm≤L≤20 mm, the size of the portion of the heat sink 120 exceeding the end of the circuit board 110 close to the air outlet is reasonable, which can effectively improve the temperature uniformity of the heat-generating components 111 while reducing the overall space occupied by the working assembly 100, and avoid excessive weight of the working assembly 100. Optionally, L may be 15 mm, but is not limited thereto. Those skilled in the art will understand that “the size of the heat sink 120 exceeds the size of the circuit board 110 by L”, and L is not limited to the above range of 10 mm≤L≤20 mm. When there is a need to improve the heat dissipation of the rear half of the circuit board or the heat-generating source, the method of extending the length of the heat sink in the present invention can be applied to adaptively adjust the length L according to different usage scenarios.

In one implementation, in combination with FIGS. 39A and 39B, each heat sink 120 includes a heat sink body 121 and a plurality of heat sink fins 122 disposed on the heat sink body 121, the heat sink body 121 is parallel to the circuit board 110, the heat sink fins 122 are perpendicular to the circuit board 110, and at least one of heat sink fins 122 is formed with at least one groove 1222.

In an example, each groove 1222 may penetrate a corresponding heat sink fin 122 in the second direction and a third direction to divide the heat sink fin 122 into a plurality of sub-heat sink fins. The calculation formula of the convection thermal resistance between the heat sink fin 122 and the air environment is: R=1/(hA), where R is the convection thermal resistance between the heat sink fin and the air environment, h is the convection heat transfer coefficient, and A is the heat dissipation area. The groove 1222 may divide the entire heat sink 122 into a plurality of sub-heat sinks spaced apart in the first direction. The air will expand and then contract in flowing through this area. After the air passes through the groove 1222 area, the disturbance becomes stronger, the convection heat transfer coefficient becomes larger, and the thermal resistance is reduced.

In an example, the at least one groove 1222 does not penetrate the corresponding heat sink fin 122 in the second direction and/or the third direction. At this time, each heat sink fin 122 is not divided into a plurality of sub-fins. The second direction is a direction in which the plurality of heat sink fins 122 are arranged, and the third direction is a direction perpendicular to the surface of the circuit board 110.

Therefore, by disposing the above-mentioned groove 1222, the overall weight of the heat sink 122 can be reduced, and the air resistance of air flowing through the heat sink 120 can be effectively reduced, the ventilation volume can be increased, and the dust accumulation on the heat sink 122 can be reduced while improving the heat-dissipating effect. Specifically, the amount of dust accumulated on the side of the heat sink 120 close to the air inlet is generally greater than the amount of dust accumulated on the side close to the air outlet. In the case where the groove 1222 is disposed at an end of the heat sink fin 122 close to the air inlet, the amount of dust accumulated at the end of the heat sink 120 close to the air inlet may be further increased. By disposing the groove 1222 at an end of the heat sink fin 122 close to the air outlet, it is possible to avoid increasing the amount of dust accumulation at the air inlet of the heat sink 120 and improve the local heat dissipation effect of the heat sink 120.

In one implementation, the groove 1222 is disposed at an end of the heat sink 122 closer to the air outlet relative to the center of the heat sink 120, that is, “the end closer to the air outlet” refers to the end closer to the air outlet with the center of the heat sink 120 as a reference standard. Therefore, since the temperature of the air at the air outlet is usually high, after the air exchanges heat with the end of the heat sink 120 close to the air outlet, the heat generated by the heat-generating components 111 in the working process cannot be effectively taken away. By disposing the groove 1222 close to the air outlet, the convection heat transfer coefficient of the air outlet area can be increased, and the thermal resistance at the air outlet can be reduced, thereby increasing the ventilation volume at the air outlet, improving the heat dissipation effect of the heat-generating components 111 at the air outlet, while also suppressing the deposition of dust, further improving the temperature uniformity of the heat-generating components 111.

In one implementation, the groove 1222 is disposed corresponding to the heat-generating components 111. Illustratively, the heat sink fins 122 of the at least one heat sink 120 are all provided with a groove 1222, a plurality of grooves 1222 are disposed in columns, and at least one column of grooves 1222 is disposed opposite to at least one column of heat-generating components 111. For example, the grooves 1222 on the plurality of heat sink fins 122 may correspond to each other in the direction in which the heat sink fins 122 are arranged, so that the grooves 1222 on the plurality of heat sink fins 122 are disposed in a column. It is possible that only the heat sink fins 122 of the first heat sink 123 are provided with grooves 1222, as shown in FIG. 39B; or only the heat sink fins 122 of the second heat sink 124 are provided with grooves 1222. It is also possible that both the heat sink fins 122 of the first heat sink 123 and the second heat sink 124 are provided with grooves 1222, in which case the grooves 1222 on the heat sink fins 122 of the first heat sink 123 and the second heat sink 124 may be different.

Optionally, the size of the groove 1222 in the first direction may be 2.5 mm to 3.5 mm (inclusive). However, it is not limited to this range. For example, when the size of the groove 1222 in the first direction is less than 2.5 mm, the width of the groove 1222 is too small, which may reduce the weight reduction effect. When the size of the groove 1222 in the first direction is greater than 3.5 mm, the width of the groove 1222 is too large, which may cause the surface area of the heat sink 122 to be too small, thereby reducing the heat dissipation effect. By enabling the size of the groove 1222 in the first direction to be 2.5 mm to 3.5 mm, the weight of the heat sink 120 can be effectively reduced while ensuring the heat dissipation effect of the heat sink 120.

Illustratively, along the first direction, the size of the groove 1222 on each heat sink fin 122 may gradually increase; or along the first direction, the size of the groove 1222 on each heat sink fin 122 may gradually decrease; or along the first direction, the size of the groove 1222 on each heat sink fin 122 may be completely equal. It is also possible that the size of the groove 1222 is positively or negatively correlated with the width of the heat sink fin 122. Of course, the present application is not limited thereto. For example, the groove 1222 on each heat sink fin 122 may be sized as needed, in combination with the variation in the width of the heat sink fin between two adjacent grooves 1222. It will be understood that the size, number, and specific position of the grooves 1222 on the heat sink fins 122 may be specifically set according to actual needs to better meet practical applications.

Therefore, by making the grooves 1222 correspond to the heat-generating components 111 in position, the heat generated in the working process by the heat-generating components 111 opposite to the grooves 1222 can be conducted to the heat sink body 121, and the air flowing through the heat sink body 121 can directly exchange heat with the heat sink body 121 to achieve heat dissipation of the heat-generating components 111. Since the convection heat transfer coefficient at the groove 1222 is large, the air resistance can be effectively reduced, thereby increasing the air volume at the heat-generating components 111 opposite to the grooves 1222 and improving the heat dissipation effect of the heat-generating components 111 opposite to the grooves 1222.

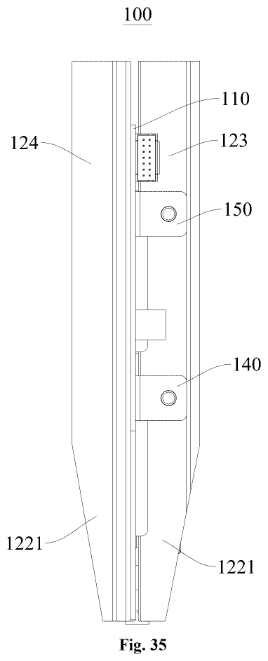

In one implementation, in combination with FIGS. 35, 36 and 39A, the at least one heat sink fin 122 includes a beveled section 1221, and a height of the beveled section 1221 gradually increases along the first direction.

In one implementation, an end of the beveled section 1221 away from the air inlet corresponds to the position of a third column of heat-generating components 111. The above-mentioned “third column of heat-generating components 111” refer to the heat-dissipating components located in the third column along the first direction. For example, in the examples of FIGS. 35, 36 and 39A, all the heat sink fins 122 of the first heat sink 123 and the second heat sink 124 include a beveled section 1221, and the beveled section 1221 is disposed close to the air inlet. Six columns of heat-generating components 111 are disposed on the circuit board 110. Along the first direction, the first three columns of heat-generating components 111 may be disposed opposite to the beveled section 1221, and the last three columns of heat-generating components 111 may be disposed opposite to the corresponding grooves 1222.

Therefore, by disposing the above-mentioned beveled section 1221, the weight of the entire heat sink fin 122 can be effectively reduced, and the thermal resistance at the air inlet can be reduced, thereby increasing the ventilation volume at the air inlet, and improving the heat dissipation effect of the heat-generating components 111 at the air inlet, while also suppressing the deposition of dust and improving the temperature uniformity of the heat-generating components 111.

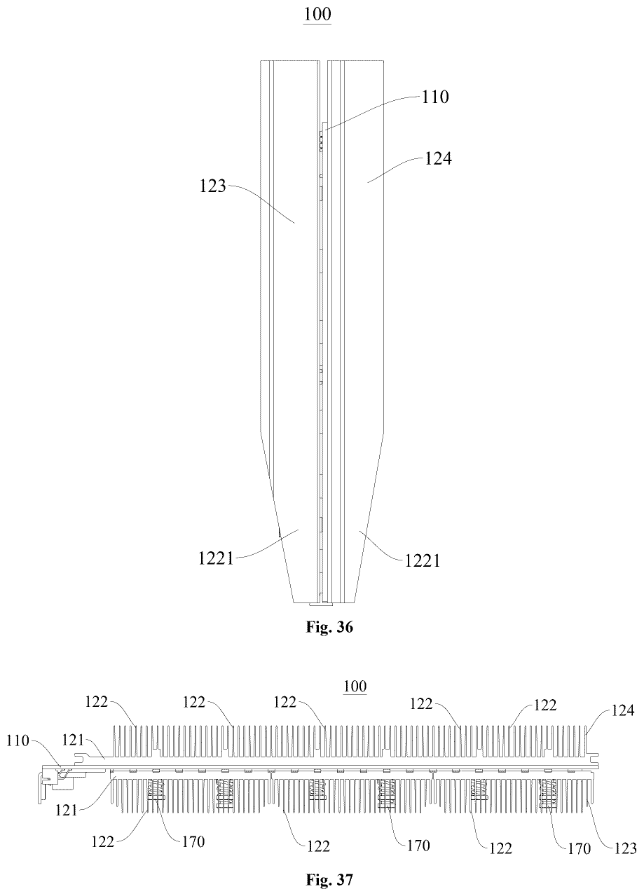

In one implementation, as shown in FIGS. 35 and 36, along the first direction, the size of the first heat sink 123 is the same as the size of the second heat sink 124. With such an arrangement, while heat dissipation of the first surface and the second surface of the circuit board 110 is achieved, the sizes of the first heat sink 123 and the second heat sink 124 may be consistent, thereby improving the versatility of the heat sink 120 and facilitating the processing of the heat sink 120.

In one implementation, the density of the heat sink fins 122 of the first heat sink 123 is the same as the density of the heat sink fins 122 of the second heat sink 124, and the height of the heat sink fins 122 of the first heat sink 123 is different from the height of the heat sink fins 122 of the second heat sink 124. For example, the height of the heat sink fins 122 of the first heat sink 123 may be greater than the height of the heat sink fins 122 of the second heat sink 124. Since the first heat sink 123 is in contact with a plurality of heat-generating components 111, by making the height of the heat sink fins 122 of the first heat sink 123 greater than the height of the heat sink fins 122 of the second heat sink 124, the area of the heat sink fins 122 of the first heat sink 123 may be greater than the area of the heat sink fins 122 of the second heat sink 124. Thus, the heat sink fins 122 of the first heat sink 123 can effectively absorb the heat generated by the plurality of heat-generating components 111 in the working process, thereby improving the heat dissipation effect.

In one implementation, the height of the heat sink fins 122 of the first heat sink 123 is the same as the height of the heat sink fins 122 of the second heat sink 124, and the density of the heat sink fins 122 of the first heat sink 123 is different from the density of the heat sink fins 122 of the second heat sink 124. For example, the density of the heat sink fins 122 of the first heat sink 123 may be greater than the density of the heat sink fins 122 of the second heat sink 124. Since the first heat sink 123 is in contact with a plurality of heat-generating components 111, by making the density of the heat sink fins 122 of the first heat sink 123 greater than the density of the heat sink fins 122 of the second heat sink 124, the area of the heat sink fins 122 of the first heat sink 123 may be greater than the area of the heat sink fins 122 of the second heat sink 124. Thus, the heat sink fins 122 of the first heat sink 123 can also effectively absorb the heat generated by the plurality of heat-generating components 111 during operation, which is beneficial to improving the heat dissipation effect. Or the density of the heat sink fins 122 of the first heat sink 123 may be smaller than the density of the heat sink fins 122 of the second heat sink 124, so that there is more heat dissipating space between adjacent heat sink fins 122 of the first heat sink 123, and the first heat sink 123 shares more air, thereby reducing air resistance, increasing ventilation, and improving dust deposition. This can also effectively dissipating heat generated during the working process of the plurality of heat-generating components 111.

In an optional implementation, the total surface area of the heat sink fins 122 of the first heat sink 123 is greater than the total surface area of the heat sink fins 122 of the second heat sink 124. This is beneficial for lowering the overall temperature of the plurality of heat-generating components 111, while lowering the maximum temperature of the plurality of heat-generating components 111.

Of course, the present application is not limited to the above. In another optional implementation, the total surface area of the heat sink fins 122 of the first heat sink 123 may be less than the total surface area of the heat sink fins 122 of the second heat sink 124. In this way, the amount of dust accumulation of the first heat sink 123 can be further reduced, and the heat generated by the plurality of heat-generating components 111 in the working process can be effectively dissipated.

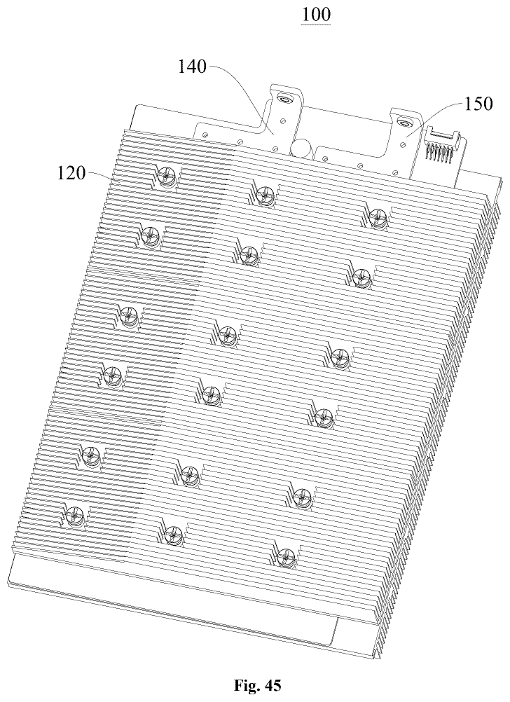

In one implementation, as shown in FIGS. 45-51, the number of heat sink fins 122 of the first heat sink 123 may be less than the number of heat sink fins 122 of the second heat sink 124. In this way, the total surface area of the heat sink fins 122 of the first heat sink 123 may be relatively small, thereby increasing the ventilation volume and reducing dust accumulation. This also can effectively dissipate the heat generated by the plurality of heat-generating components 111 in the working process.

In one implementation, with reference to FIGS. 45-51, along the second direction, an end of the second heat sink 124 exceeds a corresponding end of the first heat sink 123. For example, in the examples of FIGS. 45 to 51, along the second direction, the size of the second heat sink 124 is larger than the size of the first heat sink 123, and both ends of the second heat sink 124 exceed corresponding ends of the first heat sink. With such an arrangement, the number of heat sink fins 122 of the second heat sink 124 is relatively large, and the total surface area of its heat sink fins 122 is relatively large. The heat generated in the working process of the circuit board 110 can be effectively discharged through the heat sink fins 122 of the second heat sink 124. At the same time, the number of the first heat sink 123 may be relatively small, and the total surface area of its heat sink fins 122 is relatively small, which can further relieve the problem of serious dust accumulation on the first heat sink 123, increase the ventilation volume of the first heat sink 123, and further improve the heat dissipation effect.

In one implementation, the density of the heat-generating components 111 close to an air inlet of the heat-dissipating air duct may be greater than the density of the heat-generating components 111 close to the air outlet. Since the air entering from the air inlet is cold air and the air exiting from the air outlet is hot air, the heat generated by the heat-generating components 111 at the air inlet may be increased by increasing the density of the heat-generating components 111 at the air inlet, and the heat generated by the heat-generating components 111 at the air outlet may be reduced by reducing the density of the heat-generating components 111 at the air outlet, thereby further reducing the maximum temperature difference between the heat-generating components 111 close to the air outlet and the heat-generating components 111 close to the air inlet and improving the temperature uniformity of the heat-generating components 111.

In one implementation, as shown in FIG. 52, the plurality of the heat-generating components 111 close to the air outlet are divided into a plurality of groups of heat-generating components along the second direction, and the gap between two adjacent groups of heat-generating components is greater than the gap between two adjacent heat-generating components 111 in each group of heat-generating components.

For example, six columns of heat-generating components 111 are shown in the example of FIG. 52. For the convenience of description, the six columns of heat-generating components 111 sequentially arranged along the first direction are respectively referred to as the first heat-generating column, the second heat-generating column, . . . , the sixth heat-generating column. There are 21 heat-generating components 111 in the first to third heat-generating columns, and there are 19 heat-generating components 111 in the fourth to sixth heat-generating columns. The 21 heat-generating components 111 in the first to the third heat-generating columns are evenly spaced. The 19 heat-generating components 111 in the fourth to sixth heat-generating columns are divided into three groups of heat-generating components, and the number of heat-generating components 111 is the same in the groups of heat-generating components located at two ends in the second direction among the three groups of heat-generating components, and the number of heat-generating components 111 in the group of heat-generating components located at the middle in the second direction is less than the number of heat-generating components 111 in the groups of heat-generating components at two ends.

In this embodiment, there may be a larger heat dissipation gap between two adjacent groups of heat-generating components at the air outlet, which can reduce the temperature near the air outlet and further reduce the maximum temperature difference between the air inlet and the air outlet, thereby improving the temperature uniformity of the working assembly 100.

In one implementation, the heat-generating components 111 may be arranged in various forms, such as in chip arrays. From the first column close to the air inlet (such as the first heat-generating column mentioned above) to the last column close to the air outlet (such as the sixth heat-generating column mentioned above), the number of chips in each column is not completely equal. The number of chips in each column may be gradually decreased, for example, 21, 20, 19, 18, 17, 16; it may be partially decreased, for example, 21, 21, 21, 19, 19, 19; it may also be a jump in number, for example, 21, 21, 20, 19, 20, 21; or 21, 21, 20, 19, 18, 21; other numbers of chip arrays may also be set according to heat dissipation requirements, so that the total number of chips in the front half close to the air inlet is greater than the total number of chips in the back half close to the air outlet. The front half and the back half here may be divided in half in terms of the number of chip columns, or in half in terms of the size of the circuit board 110. As shown in FIG. 52, the total number of chips in the first three columns close to the air inlet is set to be greater than the total number of chips in the last three columns close to the air outlet.

Due to the change in the number of chips in each column, the arrangement of the chips in each row may also be combined in different forms, and the number of chips in each row may be different. For example, some rows of chips are arranged in a straight line with the center points of the chips, while the center points of some rows of chips do not form a straight line, such as in a stepped arrangement (for example, in line with the above “the number of chips in each column gradually decreases, for example, 21, 20, 19, 18, 17, 16”, the row direction presents a stepped arrangement). There are also different embodiments for the number of chips in each row. For example, in the second direction, the number of chips in the rows close to the two ends of the circuit board 110 is greater than the number of chips in the row close to the center of the circuit board 110. In short, the total chip distribution and/or quantity is divided, and the total number of chips in each part meets the preset distribution requirements.

Specifically, in the second direction, the circuit board 110 is divided into three parts from left to right based on the number of chips in the first heat-generating column, namely, the first part, the second part and the third part. The total number of chips in the first part or the third part close to the two ends of the circuit board 110 is greater than the number of chips in the second part in the middle. In another embodiment, if the circuit board 110 is divided into two parts from left to right in the second direction based on the number of chips in the first heating column, the number of chips in the first part is less than or equal to the number of chips in the second part.

With reference to FIG. 52, the above-mentioned specific division is based on the number of chips in the first heat-generating column in the second direction. In one embodiment, it is divided by way of average division. The circuit board 110 is divided into three parts from left to right. There are 21 chips in the first heat-generating column. The circuit board 110 is divided into three parts from left to right with every 7 chips in the first heat-generating column are divided into a part accordingly. Then, the total number of chips in the first part is 42, the total number of chips in the second part is 36, and the total number of chips in the third part is 42. The total number of chips in the first part (i.e., 42) or the third part (i.e., 42) close to the two ends of the circuit board 110 is greater than the number of chips in the middle second part (i.e., 36). If in the second direction, the circuit board 110 is divided into two parts from left to right based on the number of chips in the first heat-generating column, the circuit board 110 may be divided into two parts from left to right with the center axis of the 11th chip in the middle of the first heat-generating column as the dividing point, and then the number of chips in the first part (i.e., 57) is equal to the number of chips in the second part (i.e., 57). Those skilled in the art will understand that the way of division is not limited to the ways described above, and when the total number of chips in the first heat-generating column is an odd number or an even number, the way of division may be flexibly selected. Of course, the overall area formed by the edges of the chips disposed on the circuit board may be used as a reference for segmentation and division. The area may be evenly divided, or divided according to other proportions, so that the total number of chips in each part meets the preset distribution requirements.

In short, the arrangement of the chips may be set according to the heat dissipation conditions at various positions in the air duct. For example, the ambient temperature at the air inlet is low and the overall heat dissipating efficiency is high, more chips may be arranged. The ambient temperature at the air outlet is high and the overall heat dissipating efficiency is low, fewer chips may be arranged, and the total number of chips close to the air outlet is less than the total number of chips close to the air inlet. At the same time, the temperatures at the upper and lower ends of the circuit board 110 in the direction perpendicular to the air direction are lower than the temperature at the center of the circuit board 110. In this case, more chips may be arranged at the two ends and fewer chips may be arranged at the center. The total number of chips at the two ends is greater than the total number of chips in the center. Alternatively, after being divided into two parts, the total number of chips in the lower half may be greater than the total number of chips in the upper half. This is a completely different design idea from conventionally changing the thermal resistance of the heat sink to achieve uniform temperature.

In one implementation, with reference to FIGS. 31 and 39A-42, a first connection base 140 and a second connection base 150 are provided at an end of the circuit board 110 in the second direction, and the first connection base 140 and the second connection base 150 are spaced apart in the first direction, wherein the second direction is perpendicular to the first direction. For example, the first connection base 140 and the second connection base 150 may be aluminum bases or copper bases. The thickness of the connection base when it is made of aluminum may be greater than when it is made of copper. Therefore, by disposing the first connection base 140 and the second connection base 150, compared with the way of disposing a plurality of connection plates in the prior art, the first connection base 140 and the second connection base 150 are simpler in structure and easier to process, which can effectively improve the assembly efficiency of the working assembly 100. Illustratively, through holes are provided on the first connection base 140 and the second connection base 150, and the through holes may be used for welding alignment. In addition, the through holes provided on the first connection base 140 and the second connection base 150 are also conducive to exhausting gas when welding the first connection base 140 and the second connection base 150.

Further, as shown in FIGS. 39A-42, the first connection base 140 and the second connection base 150 both include a connection body 141 and an extension portion 142. The connection body 141 is connected to the first surface of the circuit board 110, one end of the extending portion 142 is connected to the connection body 141, and the other end of the extending portion 142 extends away from the circuit board 110 along a third direction, wherein the third direction is perpendicular to the first surface. For example, the extension portion 142 may include a first connection segment, a second connection segment, and a third connection segment. One end of the first connection segment may be connected to the connection body 141, and the other end of the first connection segment may be obliquely arranged in the direction away from the circuit board 110. One end of the second connection segment may be connected to the other end of the first connection segment, and the second connection segment may be disposed away from the first connection segment in a direction parallel to the first surface. One end of the third connection segment may be connected to the other end of the second connection segment, and the other end of the third connection segment may be disposed away from the circuit board 110 in a direction perpendicular to the first surface.

Therefore, by disposing the above-mentioned connection body 141 and extension portion 142, a firm connection between the entire connection base (that is, the above-mentioned first connection base 140 and the second connection base 150) and the circuit board 110 can be achieved through the connection body 141, and the extension portion 142 may extend outward to connect with a conductive connection portion, thereby realizing power supply for the circuit board 110.

In one implementation, an avoidance slot 143 is defined between the extension portion 142 and the first surface. For example, the avoidance slot 143 is co-defined by the first connection segment, the second connection segment and the first surface of the circuit board 110. In this way, the wiring harness may pass through the avoidance slot 143, thereby effectively playing the role of avoidance routing.

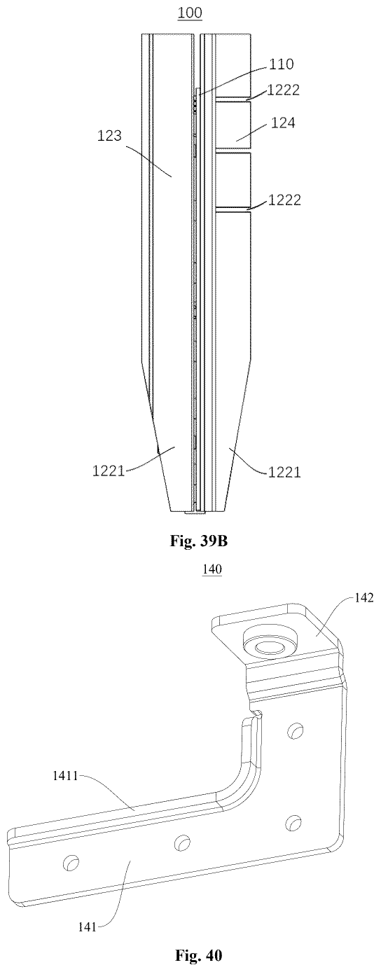

In one implementation, as shown in FIG. 40, the edge of the connection body 141 has a flanging 1411 extending in a direction away from the circuit board 110. With such a configuration, the flanging 1411 can effectively resist bending, so as to ensure the connection between the connection body 141 and the circuit board 110 to be more secure, preventing the edge of the connection body 141 from warping, and improving reliability.

In one implementation, with reference to FIGS. 39A, 42 and 43, a plurality of heat-generating components 111 are disposed on the first surface of the circuit board 110, a sealing member 160 is disposed between the first heat sink 123 and the circuit board 110, and the sealing member 160 is disposed close to the air inlet. For example, the sealing member 160 may be a rubber member. Therefore, by disposing the above-mentioned sealing member 160, the sealing performance between the first heat sink 123 and the circuit board 110 at the air inlet can be improved to prevent moisture from entering through the gap between the first heat sink 123 and the circuit board 110, thereby protecting the heat-generating components 111 close to the air inlet and meanwhile preventing air leakage.

In one implementation, with reference to FIGS. 39A, 42 and 43, the sealing member 160 includes a first sealing portion 161 and a second sealing portion 162. The first sealing portion 161 abuts against the edges of the circuit board 110 and the first heat sink 123 close to the air inlet, and the second sealing portion 162 is disposed on a side of the first sealing portion 161 away from the air inlet, and the second sealing portion 162 is located in a gap between the first heat sink 123 and the circuit board 110. Illustratively, the second sealing portion 162 divides the first sealing portion 161 into two parts, one of which contacts at least an edge of the heat sink body 121 of the first heat sink 123, and the other of which contacts at least an edge of the circuit board 110. There is an inlet between the edge of the heat sink body 121 of the first heat sink 123 close to the air inlet and the edge of the circuit board 110 close to the air inlet, and the second sealing portion 162 extends into the gap between the first heat sink 123 and the circuit board 110 through the inlet.

Therefore, by arranging the first sealing portion 161 and the second sealing portion 162 described above, the first sealing portion 161 has a better shielding effect, preventing moisture at the air inlet from directly contacting the heat sink body 121 of the first heat sink 123 or the circuit board 110, and the second sealing portion 162 has an effective sealing effect, further preventing moisture from entering the gap between the first heat sink 123 and the circuit board 110, thereby further improving the sealing of the first heat sink 123 and the circuit board 110 at the air inlet.

In one implementation, in conjunction with FIGS. 45-51, the working assembly 100 may not be provided with the sealing member 160, thereby ensuring the heat dissipation performance of the entire working assembly 100.

In one implementation, as shown in FIGS. 39A and 44, the circuit board 110 and the heat sink 120 may be connected via a connection member. For example, the connection member may be a screw, an elastic connection member, or the like.

In one implementation, as shown in FIGS. 39A and 44, the circuit board 110 and the heat sink 120 are connected by a spring screw 170, and the spring screw 170 includes a screw 172 and a spring 171 sleeved on the screw 172, and the end of the spring 171 close to the circuit board 110 extends in a direction away from the circuit board 110. For example, in the examples of FIGS. 39A and 44, the tail of the spring 171 is folded in the direction away from the circuit board 110. Therefore, although the spring 171 has a sharp end, the above-mentioned arrangement can prevent the end of the spring 171 from scraping aluminum chipping due to the contact between the end of the spring 171 and the surface of the circuit board 110, thereby avoiding damage to the circuit board 110 and improving the integrity and reliability of the circuit board 110.

An electronic device 200 according to an embodiment of the second aspect of the present application, such as a computing device, as shown in FIGS. 1-9A, includes the working assembly 100 according to any one of the implementations of the first aspect of the present application.

By adopting the working assembly 100 described above, the electronic device 200 according to the embodiments of the present application, such as a computing device, can reduce the maximum temperature difference between the heat-generating components 111 close to the air outlet and the heat-generating components 111 close to the air inlet, thereby improving the temperature uniformity of the heat-generating components 111.

In one implementation, with reference to FIGS. 1-9A, the electronic device 200 includes a housing 210 and a fan assembly 220. A heat-dissipating air duct having an air inlet and an air outlet is defined in the housing 210, and at least one working assembly 100 is disposed in the heat-dissipating air duct. The working assembly 100 includes a circuit board 110 and a plurality of heat sinks 120. The plurality of heat sinks 120 are disposed on at least one side of the circuit board 110. For example, the heat sinks 120 may be disposed on both sides of the circuit board 110. The surface of the circuit board 110 is parallel to a first direction, which extends from the air inlet to the air outlet. The fan assembly 220 is disposed on a side of the housing 210 close to the air inlet.

Illustratively, three working assemblies 100 are shown in FIG. 9A, and the three working assemblies 100 are arranged at intervals along a direction perpendicular to the surface of the circuit board 110. The heat sinks 120 may each include a heat sink body 121 and a plurality of heat sink fins 122. The plurality of heat sink fins 122 are disposed on a side of the heat sink body 121 at intervals along a second direction (for example, the vertical direction in FIG. 9A), wherein the second direction is perpendicular to the first direction and parallel to the surface of the circuit board 110.

The heat sink body 121 of the first heat sink 123 may contact the heat-generating components 111 on the first surface, and the heat sink body 121 of the second heat sink 124 may contact the second surface of the circuit board 110. The heat generated during the operation of the heat-generating components 111 may be conducted to the first heat sink 123 and the second heat sink 124. A heat dissipation channel extending along the first direction may be defined between two adjacent heat sink fins 122 and the heat sink body 121. When the fan assembly 220 is working, cold air enters from the air inlet, flows along the heat dissipation channels of the first heat sink 123 and the second heat sink 124, and exchanges heat with the first heat sink 123 and the second heat sink 124. The hot air after heat exchange flows out from the air outlet, thereby achieving heat dissipation of the working assembly 100.

By disposing the fan assembly 220 on the side of the housing 210 close to the air inlet so that the fan assembly 220 and the air outlet are located on opposite sides of the housing 210, when part of the working assemblies 100 is damaged, only the damaged working assembly 100 needs to be removed and taken out from the air outlet, and then the working assembly 100 with intact function is placed into the housing 210 through the air outlet and installed, without removing the fan assembly 220. This enables more convenient installation and disassembly of the working assembly 100 and can effectively improve the efficiency of servicing and replacement of the working assembly 100.

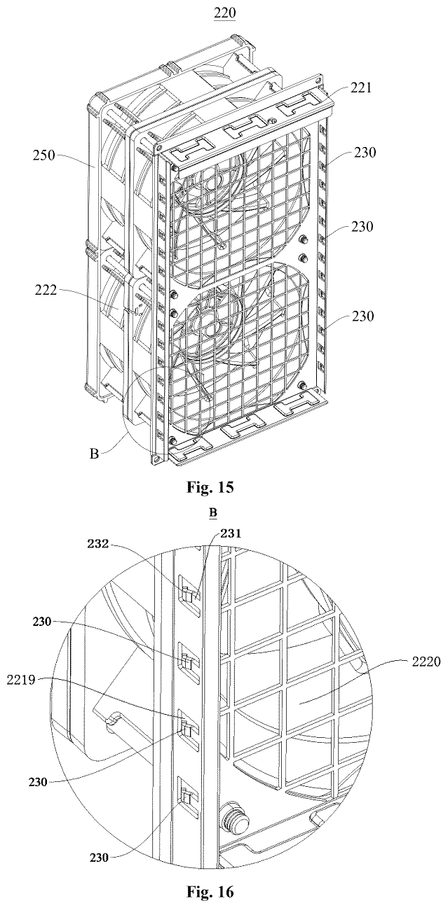

In one implementation, with reference to FIGS. 9A-15, the fan assembly 220 includes a mounting member 221 and a plurality of fan modules 222. The mounting member 221 is connected to the housing 210, and the plurality of fan modules 222 are connected to a side of the mounting member 221 facing away from the housing 210. For example, in the examples of FIGS. 15, 17 and 18, the mounting member 221 is greater than the fan module 222 in outline size. A plurality of first ventilation holes are formed on the portion of the mounting member 221 facing away from the fan module 222. When the fan module 222 is of the blowing type and the fan module 222 is operating, external air enters the heat-dissipating air duct through the plurality of first ventilation holes under the action of the fan module 222, exchanges heat with the first heat sink 123 and the second heat sink 124, and then flows out from the air outlet. When the fan module 222 is of suction type and the fan module 222 is operating, external air enters the heat-dissipating air duct through a plurality of second ventilation holes 2137 under the action of the fan module 222, exchanges heat with the first heat 123 and the second heat 124, and then flows out from the plurality of first ventilation holes 2220.

Therefore, by disposing the mounting member 221 and the plurality of fan modules 222 described above, the mounting member 221 can firmly fix the fan module 222 on the housing 210, thereby improving the structural stability and reliability of the entire electronic device 200. The plurality of fan modules 222 can increase the ventilation volume of the heat-dissipating air duct, reduce air resistance, and inhibit the deposition of dust on the heat sink 120, thereby effectively improving the heat dissipation effect of the working assembly 100.

In one implementation, the plurality of fan modules are divided into a plurality of fan groups arranged vertically. Each fan group includes two fan modules. The two fan modules are disposed opposite to each other in a direction from the air inlet to the air outlet.

In one implementation, through holes are formed at four corners of each fan module, threaded holes are formed on the mounting member, and threaded fasteners pass through the through holes of the two fan modules and are threadedly connected to corresponding threaded holes, respectively.

In one implementation, as shown in FIGS. 11 and 14-16, at least one first elastic component is provided on the mounting member 221, and the first elastic component is pressed tightly between the mounting member 221 and the corresponding side wall of the housing 210 to achieve a secure installation between the mounting member 221 and the housing 210 and prevent the mounting member 221 from falling off the housing 210.

In one implementation, as shown in FIGS. 11 and 14-16, the mounting member 221 includes a mounting body 2213, a mounting top plate 2215 and a mounting bottom plate 2216 that are oppositely disposed, two mounting side plates 2214, and a first bent portion 2217. A fan module 222 is connected to the mounting body 2213, and a plurality of first ventilation holes are formed on the mounting body 2213. The mounting top plate 2215 and the mounting bottom plate 2216 are disposed on a side of the mounting body 2213 facing away from the fan module. The mounting top plate 2215 is connected to the upper part of the mounting body 2213, and the mounting bottom plate 2216 is connected to the lower part of the mounting body 2213. The two mounting side plates 2214 are disposed on a side of the mounting body 2213 facing away from the fan module 222. Furthermore, the two mounting side plates 2214 are respectively connected to two sides of the mounting body 2213. The first elastic component is disposed on at least one of the two mounting side plates 2214. The first bent portion 2217 is connected to an end of the mounting top plate 2215 facing away from the mounting body 2213. In one implementation, the working assembly abuts against the first bent portion 2217, the mounting top plate 2215, the mounting bottom plate 2216 and each mounting side plate 2214 is perpendicular to the mounting body 2213, and the first bent portion 2217 is parallel to the mounting body 2213. In one implementation, a plurality of reinforcing ribs 2218 (such as I-shaped ribs) arranged at intervals are provided on the mounting top plate 2215 and/or the mounting bottom plate 2216.

Illustratively, in combination with FIGS. 11 and 13-16, the mounting top plate 2215, the mounting bottom plate 2216 and each mounting side plate 2214 may all be perpendicular to the mounting body 2213. The mounting top plate 2215 is connected between the mounting body 2213 and the first bent portion 2217, and the first bent portion 2217 is parallel to the mounting body 2213. After installation, the working assembly 100 may abut against the first bent portion 2217, so that, on one hand, there is a certain gap between the mounting member 221 and the working assembly 100 in the first direction. When the external air enters the heat-dissipating air duct from the fan module 222, it may flow evenly in the gap between the mounting member 221 and the working assembly 100, and then flow through the first heat sink 123 and the second heat sink 124 to improve the heat dissipation effect. On the other hand, the first bent portion 2217 may play an effective role in blocking the air, so that the air entering from the air inlet may flow into the working assembly 100 as much as possible, thereby avoiding the waste of air volume.

A plurality of I-shaped reinforcement ribs 2218 may be provided on the mounting top plate 2215 and the mounting bottom plate 2216 to prevent the mounting top plate 2215 and the mounting bottom plate 2216 from bending and warping, thereby improving the structural strength of the entire mounting component 221 and ensuring the structural stability of the electronic device 200.

In one implementation, the at least one first elastic component includes a plurality of first elastic clips 230 spaced apart from each other vertically, and free ends of the first elastic clips are pressed tightly between the mounting side plate 2214 and the corresponding side wall of the housing.

Illustratively, a plurality of via holes 2219 disposed at intervals vertically may be formed on the mounting side plate 2214, and a plurality of first elastic clips 230 are disposed in the plurality of via holes 2219 in a one-to-one correspondence. One end of each first elastic clip 230 is connected to the edge of the corresponding via hole 2219, and the other end (i.e., the free end) of each first elastic clip 230 extends in a direction opposite to the first direction. When the mounting member 221 is mounted on the housing 210, the side wall of the housing 210 presses the other end of each first elastic clip 230, so that each first elastic clip 230 generates elastic deformation. When the mounting member 221 is removed from the housing 210, the first elastic clip 230 returns to its original state. The first elastic clips 230 are all made of metal.

In one example, as shown in FIG. 16, each first elastic clip 230 may include a connection portion 231 and an abutment portion 232. One end of the connection portion 231 is connected to the first edge of the corresponding via hole 2219. One end of the abutment portion 232 is connected to the other end of the connection portion 231, and the other end of the abutment portion 232 is spaced apart from the opposite side edge of the first edge. The abutment portion 232 abuts against the corresponding side wall of the housing 210.

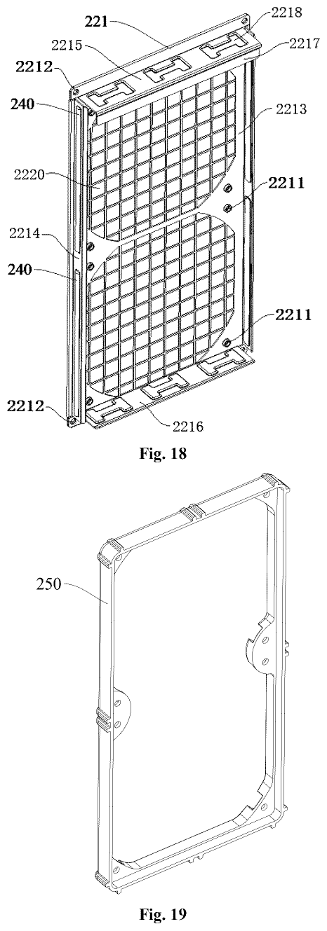

Therefore, the mounting member 221 and the housing 210 may be electrically connected via the plurality of first elastic clips 230, thereby playing an effective shielding and grounding role and improving the safety of the electronic device 200. In another implementation, with reference to FIG. 18 in combination with FIG. 11, the at least one first elastic component described above includes a first conductive foam 240 extending in the vertical direction, and the mounting member 221 is in elastic contact with the corresponding side wall of the housing 210 through the first conductive foam 240. For example, the first conductive foam 240 may be adhered to the two mounting side plates 2214 by an adhesive. Optionally, the first conductive foam 240 may be a conductive foam, but is not limited thereto. In this way, the mounting member 221 and the housing 210 may be electrically connected via the first conductive foam 240, thereby also playing an effective shielding and grounding role and improving the safety of the electronic device 200.

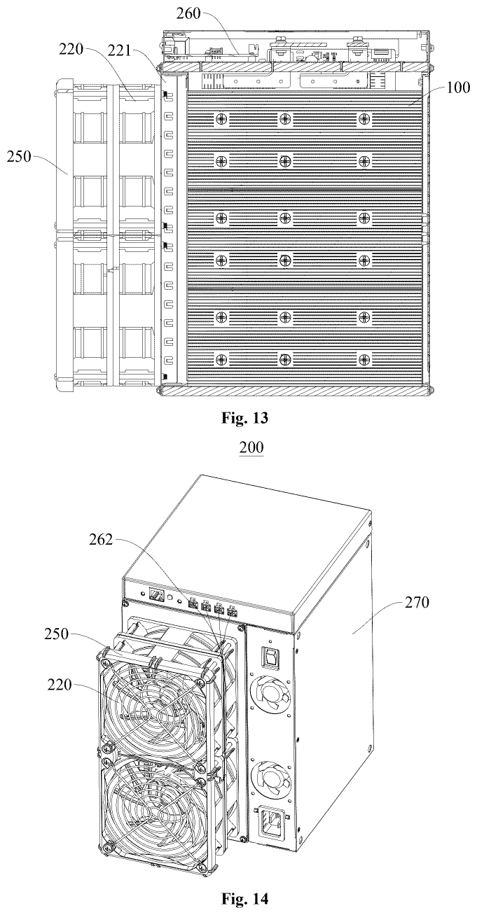

In one implementation, as shown in FIG. 13, the fan module 222 and the working assembly 100 are spaced apart in the first direction. For example, in the example of FIG. 13, there is a certain gap between the mounting member 221 and the working assembly 100 in the first direction. When the external air enters the heat-dissipating air duct from the fan module 222, it can flow evenly in the gap between the mounting member 221 and the working assembly 100, and then flow through the first heat sink 123 and the second heat sink 124. Thus, the gap between the fan module 222 and the working assembly 100 may allow air to flow into the heat sink 120 more evenly, thereby improving the heat dissipation effect.

In one implementation, with reference to FIGS. 14-19, a flexible protective cover 250 is disposed on a side of the fan module 222 away from the mounting plate, and the flexible protective cover 250 is sleeved on an outer periphery of the fan module 222. Therefore, the flexible protective cover 250 configured in this way can effectively protect the edges and corners of the fan module 222, thus preventing the fan module 222 from being worn, and it may prevent the edges and corners of the fan module 222 from scratching workers, thereby improving safety. Optionally, the material of the flexible protective cover 250 may be soft rubber material, but is not limited thereto.

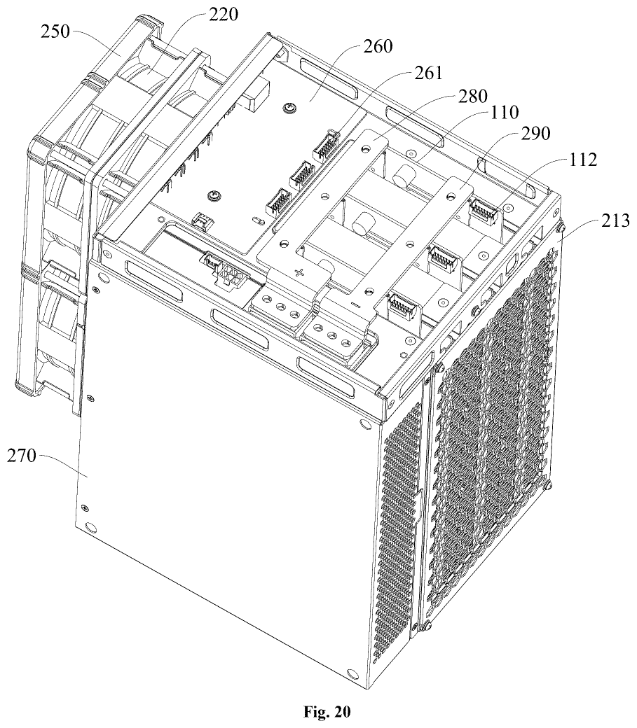

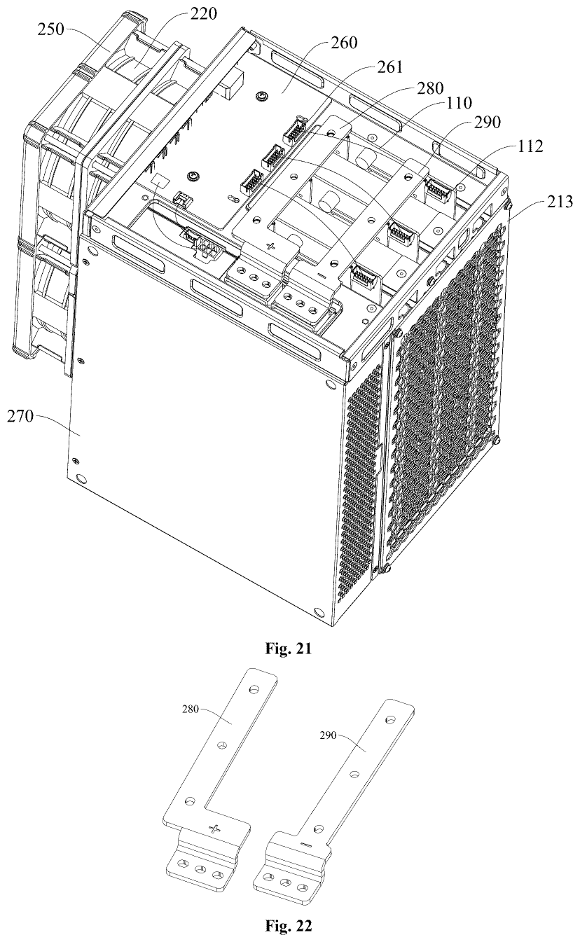

In one implementation, as shown in FIGS. 20 and 21, a control board 260 is provided on the top of the housing 210, and a plurality of fan interfaces 262 are provided on the control board 260. The plurality of fan interfaces 262 are connected to the plurality of fan modules 222 in a one-to-one correspondence, wherein the plurality of fan interfaces 262 are all disposed close to the air inlet. In this way, the plurality of fan interfaces 262 are disposed close to the plurality of fan modules 222, which facilitates the wiring between the plurality of fan interfaces 262 and the plurality of fan modules 222.

Illustratively, a first signal socket 112 is disposed on the circuit board 110, and a second signal socket 261 is disposed on the control board 260, and the second signal socket 261 is connected to the first signal socket 112. For example, in the examples of FIGS. 20 and 21, there are three second signal sockets 261, and the three second signal sockets 261 may be connected one-to-one with the circuit boards 110 of the three working assemblies 100 through three first cables, so that the control board 260 can control the operation of the circuit board 110.

Illustratively, the second signal sockets 261 are close to the first signal sockets 112. Illustratively, when there are three second signal sockets 261, there are three first signal sockets 112, wherein the three second signal sockets 261 are disposed on a side of the control board 260 close to the first signal sockets 112. Such a configuration may facilitate the connection between the second signal sockets 261 and the first signal sockets 112 using the shortest connection line.

Illustratively, there are four fan interfaces 262 and four fan modules 222, and the four fan interfaces 262 may be connected to the four fan modules 222 in a one-to-one correspondence through four second cables, so that the control board 260 can control the operation of the working modules.

Illustratively, the four fan modules 222 are divided into two groups, and two fan modules 222 in each group are connected together by screws and fixed to the mounting member 221 by screws. Each fan module 222 is provided with through holes at four corners for screws to pass through, and correspondingly, the mounting member 221 is provided with threaded holes 2211 for screws to pass through to achieve assembly between the fan module 222 and the mounting member. Illustratively, the mounting member 221 is further provided with a plurality of fixing holes 2212 for fixing the mounting member 221 to the housing 210. For example, four fixing holes 2212 are provided at the four corners of the mounting member 221, and correspondingly, fixing holes are provided on the housing 210.

Therefore, through the above configuration, on the one hand, signal connection between the control board 260 and the fan module 222 and between the control board 260 and the circuit board 110 can be achieved; on the other hand, by disposing all of the plurality of fan interfaces 262 close to the air inlet, the plurality of fan interfaces 262 can be centrally disposed on the control board 260, and the structure is more compact, occupying less space, and facilitating the spatial layout of other modules on the control board 260.

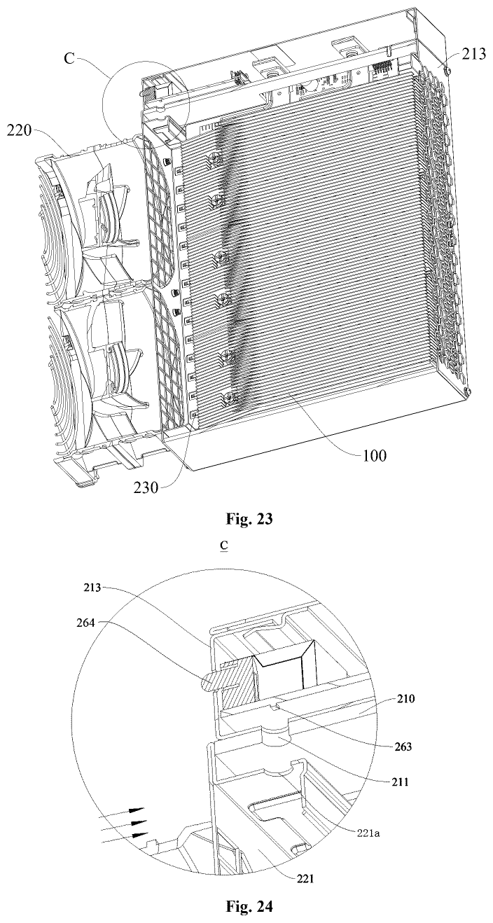

In one implementation, with reference to FIGS. 23-25B, a top housing 212 is disposed on the top of the housing 210, and a control board 260 is disposed in the top housing 212. The control board 260 is provided with a temperature sensor 263 for sensing the temperature at the air inlet. In this way, a user may know the temperature at the air inlet in real time, avoid the temperature of the air entering from the air inlet being too high, and endow the working assembly 100 with a better heat dissipation effect, thereby ensuring the normal operation of the working assembly 100 and effectively extending the service life of the entire electronic device 200.

In one implementation, as shown in FIGS. 23 and 24, the temperature sensor 263 is disposed at the bottom of the control board 260, and the temperature sensor 263 is located within the top housing 212. The top surface of the housing 210 is formed with a ventilation hole 211 communicated with the heat-dissipating air duct, and the ventilation hole 211 corresponds to the temperature sensor 263 in position. For example, in the examples of FIGS. 23 and 24, a third ventilation hole 221a penetrating in the thickness direction is formed on the top of the mounting member 221, and the third ventilation hole 221a, the ventilation hole 211 and the temperature sensor 263 correspond to each other in the vertical direction.

Therefore, the temperature sensor 263 in the above implementations can sense the temperature at the air inlet through the ventilation hole 211. Moreover, the temperature sensor 263 may be hidden in the top housing 212 to prevent the temperature sensor 263 from direct contact with the external environment, so that the top housing 212 may effectively protect the temperature sensor 263 and prevent the temperature sensor 263 from being damaged, and may make the appearance of the electronic device 200 more neat and beautiful.

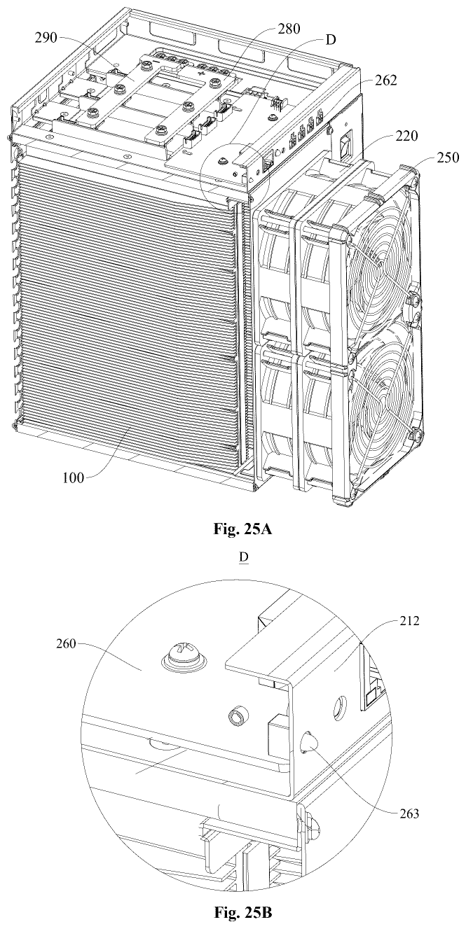

In another implementation, with reference to FIGS. 25A and 25B, the temperature sensor 263 is disposed on the top of the control board 260, and the temperature sensor 263 protrudes from a side surface of the top housing 212 close to the fan assembly 220. For example, in the examples of FIGS. 25A and 25B, a passage hole may be formed on the side of the top housing 212 close to the air inlet, the temperature sensor 263 may be set on the side of the control board 260 close to the air inlet, and the temperature sensor 263 protrudes out of the top housing 212 from the passage hole. With such configuration, the temperature sensor 263 can directly protrude out of the top housing 212 to sense the temperature at the air inlet, and no holes need to be opened on the housing 210 and the mounting member 221, thereby making the structure of the housing 210 simpler and easier to process.

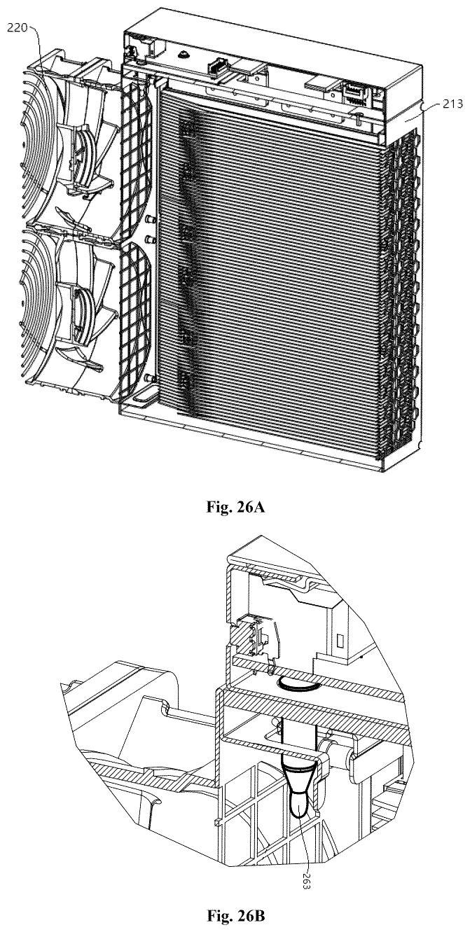

Of course, the present application is not limited thereto. In another implementation, as shown in FIGS. 26A and 26B, the free end of the temperature sensor 263 may pass through the top of the housing 210 and protrude into the housing 210 and be opposite to the fan assembly 220. In this way, the free end of the temperature sensor 263 can protrude into an air inlet cavity of the housing 210 to detect the temperature of the air input by the fan assembly 220, and can sense the temperature of the air inlet more accurately.

In the process of implementing the present invention, the inventors found that the indicator light of the electronic device 200 is usually disposed in the middle of the control board of the electronic device 200. When a plurality of fans are connected in series (for example, 4 fans) and installed on a front face of the electronic device 200, due to the viewing angle, the fan will block the indicator light, affecting the observation of the operation and maintenance personnel, especially when the electronic device 200 needs to be placed on a rack, sometimes at a higher position, in which case the fan will more easily block the indicator light.

Based on this, in one implementation, as shown in FIGS. 23 and 24, the electronic device 200 may further include an indicator light 264 to indicate the working status of the electronic device 200. The indicator light 264 is disposed on a side of the control board close to the air inlet, and is located at an end of the control board near the side of the air inlet.

Since the indicator light 264 is disposed at the end of the side of the control board, the indicator light may be observed from one side of the electronic device 10, thus avoiding the situation where the fan blocks the indicator light.

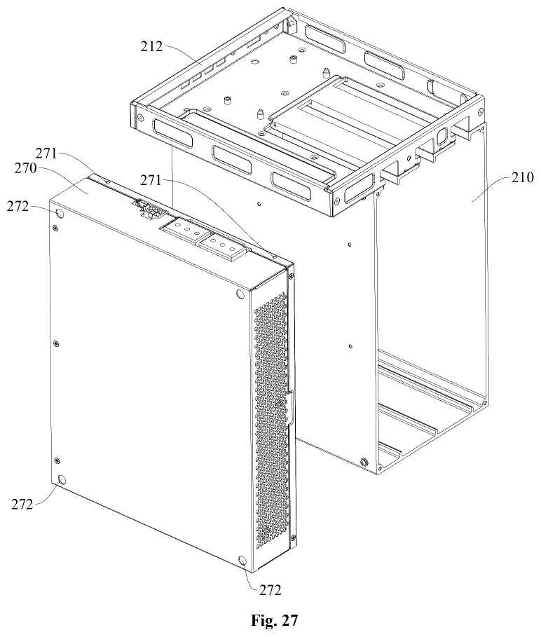

In one implementation, as shown in FIGS. 27-29B, the electronic device 200 further includes: a power supply module 270 disposed on one side of the housing 210 in a third direction and configured to supply power to the circuit board 110 and the fan assembly 220, wherein the third direction is perpendicular to the surface of the circuit board 110.

Illustratively, the housing 210 is generally a cuboid structure, and the housing 210 may include a top surface, a bottom surface, and four side surfaces, and the four side surfaces are respectively connected between the top surface and the bottom surface. The top surface and the bottom surface are opposite to each other in the second direction. The top of the power supply module 270 is connected to the top housing 212, and the side surfaces of the power supply module 270 is connected to side surfaces of the housing 210.

Along the third direction, the top housing 212 includes two first side surfaces that are disposed opposite to each other and two second side surfaces that are disposed opposite to each other, wherein one of the two second side surfaces is flush with the corresponding fourth side surface of the housing 210, the other of the two second side surfaces is flush with the corresponding side surface of the power supply module 270, each first side surface is flush with the corresponding side surface of the housing 210 and the power supply module 270 at the same time, and the bottom surface of the power supply module 270 is flush with the bottom surface of the housing 210.

Specifically, for example, the two first side surfaces of the top housing 212 may be a front side surface and a rear side surface, respectively, and the two second side surfaces of the top housing 212 may be a left side surface and a right side surface, respectively. The front side surface of the top housing 212 may be flush with the front side surface of the housing 210 and the front side surface of the power supply module 270, the rear side surface of the top housing 212 may be flush with the rear side surface of the housing 210 and the rear side surface of the power supply module 270, the left side surface of the top housing 212 may be flush with the left side surface of the housing 210, the right side surface of the top housing 212 may be flush with the right side surface of the power supply module 270, and the bottom surface of the power supply module 270 is flush with the bottom surface of the housing 210.

It should be noted that the above-mentioned “front” refers to the direction close to the air inlet of the heat-dissipating air duct, and the opposite direction is defined as “rear”, that is, the direction close to the air outlet of the heat-dissipating air duct. “Left” refers to the direction extending along the power supply module 270 toward the housing 210; “right” refers to the direction extending along the housing 210 toward the power supply module 270. Correspondingly, the “front side surface” refers to the side surface close to the air inlet of the heat-dissipating air duct, and the “rear side surface” refers to the side surface close to the air outlet of the heat-dissipating air duct. The “left side surface” refers to the side surface in the direction from the power supply module 270 toward the housing 210, and the “right side surface” refers to the side surface in the direction from the housing 210 toward the power supply module 270.

Therefore, through the above-mentioned power supply module 270, while supplying power to the circuit board 110 and the fan assembly 220, the power supply module 270 may effectively utilize the space between the top housing 212 and the housing 210, thereby making the structure of the entire electronic device 200 more compact and the appearance more neat and beautiful.

In one implementation, as shown in FIGS. 27-30B, at least one positioning hole 271 is formed on one of the power supply module 270 and the top housing 212, and at least one positioning protrusion is provided on the other of the power supply module 270 and the top housing 212, and the positioning protrusion is fitted into the corresponding positioning hole 271. At least one through hole 272 is formed on one of the power supply module 270 and the housing 210, and at least one threaded hole corresponding to the through hole 272 is formed on the other of the power supply module 270 and the housing 210. The threaded fastener 273 is suitable for passing through the through hole 272 and being threadedly connected with the threaded hole.

For example, in the examples of FIGS. 27-30B, two positioning holes 271 are formed on the top of the power supply module 270, and the two positioning holes 271 are disposed at intervals along the first direction. Correspondingly, two positioning protrusions disposed at intervals in the first direction may be disposed on the bottom surface of the top housing 212, and the two positioning protrusions correspond one-to-one to the two positioning holes 271. Four through holes 272 are formed on a side surface of the power supply module 270, and the four through holes 272 are respectively located at the four corners of the power supply module 270. Four threaded holes corresponding one-to-one to the four through holes 272 are formed on the second side surface of the housing 210. During installation, the two positioning protrusions may be respectively fitted into the corresponding positioning holes 271 to achieve positioning of the power supply module 270. Then, four threaded fasteners 273 are respectively passed through the corresponding through holes 272 and threadedly connected with the corresponding threaded holes to fix the power supply module 270.

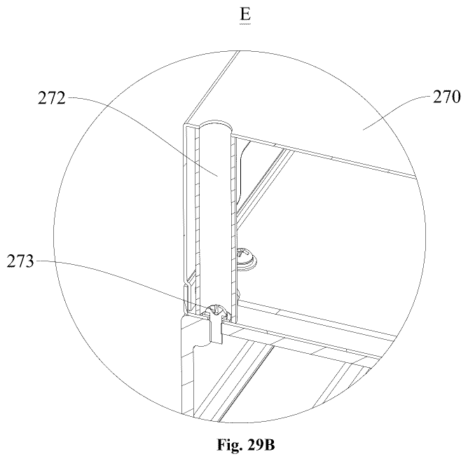

In one example, as shown in FIGS. 29A and 29B, all the threaded fastener 273 may be short screws. In this case, the threaded fasteners 273 may pass through one of the side walls of the power supply module 270 and be threadedly connected to the threaded holes on the housing 210 respectively. At this time, one of the side walls of the power supply module 270 is pressed tightly between the head of the threaded fasteners 273 and the housing 210.

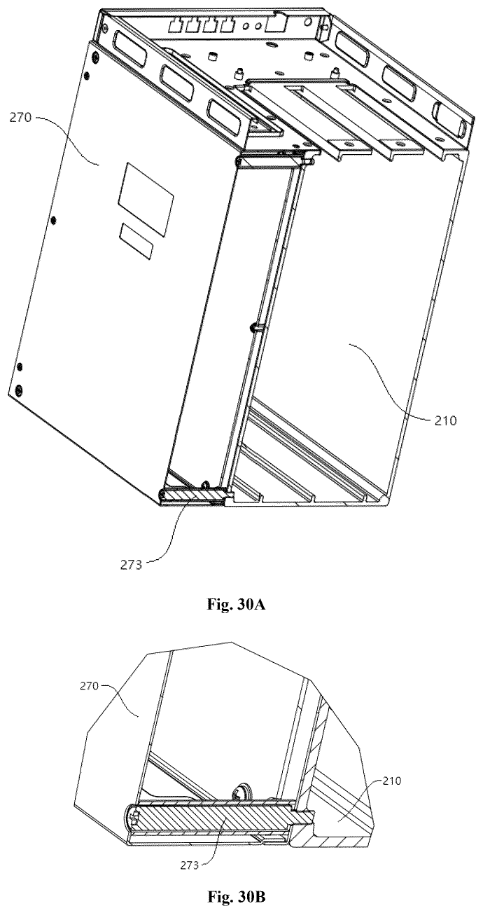

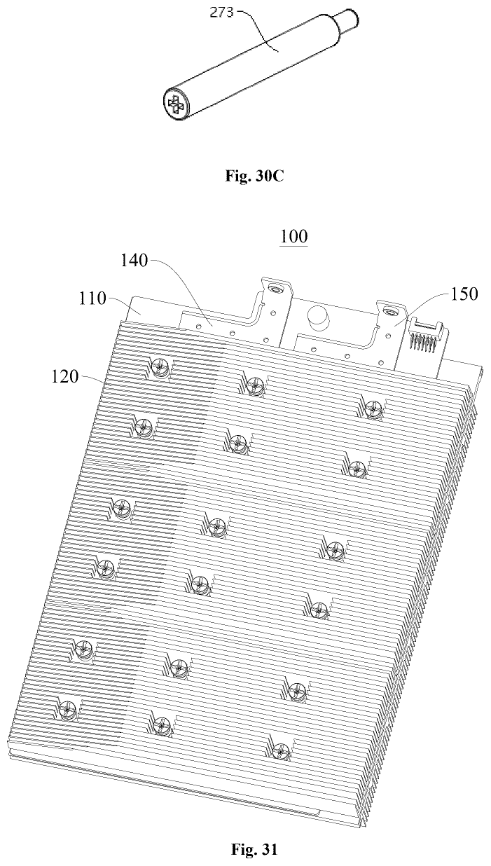

In another example, as shown in FIGS. 30A-30C, all the threaded fastener 273 may be long screws. In this case, the threaded fasteners 273 may pass through two side walls of the power supply module 270 and be threadedly connected to the threaded holes on the housing 210 respectively. At this time, the entire power supply module 270 is pressed tightly between the head of the threaded fasteners 273 and the housing 210. This fixing method has better visibility and facilitates the installation and removal of threaded fasteners 273 such as screws.

Of course, it is also possible to have some threaded fasteners 273 as short screws and others as long screws, which is not limited in the present application.

Therefore, the power supply module 270 may be positioned relative to the housing 210 in advance by the cooperation of the positioning protrusion and the positioning hole 271, preventing the power supply module 270 from shifting during the process of being assembled with the housing 210, thereby improving installation efficiency. Moreover, the power supply module 270 and the housing 210 may be directly threadedly connected via the threaded fastener 273, which eliminates the need for a bracket between the power supply module 270 and the housing 210 and makes the structure simpler.

In one implementation, with reference to FIGS. 20-22, the electronic device 200 further includes a first conductive connection member 280 and a second conductive connection member 290. Specifically, one part of the first conductive connection member 280 is electrically connected to the power supply module 270, and the other part of the first conductive connection member 280 is electrically connected to the first connection base 140 of the working assembly 100. One part of the second conductive connection member 290 is electrically connected to the power supply module 270, and the other part of the first conductive connection member 290 is electrically connected to the second connection base 150 of the working assembly 100.

For example, in the examples of FIGS. 20-22, the bottom surface of the above-mentioned other part of the first conductive connection member 280 may contact the top surfaces of the third connection segments of the three first connection bases 140, and the first fastener is suitable for passing through the first conductive connection member 280 to connect with the third connection segment of the corresponding first connection base 140. The bottom surface of the above-mentioned other part of the second conductive connection member 290 may contact the top surfaces of the second connection segments of the three second connection bases 150, and the second fastener is suitable for passing through the second conductive connection member 290 to connect with the third connection segment of the corresponding second connection base 150. The above-mentioned other portion of the first conductive connection member 280 may be parallel to the above-mentioned other portion of the second conductive connection member 290, and both extend along the third direction. The first conductive connection member 280 may be a positive electrode conductive bar, and the second conductive connection member 290 may be a negative electrode conductive bar.

Therefore, by disposing the first conductive connection member 280 and the second conductive connection member 290 described above, electrical connection between the power supply module 270 and the circuit board 110 may be achieved, so that current may be input from the power supply module 270 into the circuit board 110 to achieve power supply for the circuit board 110. Moreover, the first conductive connection member 280 and the second conductive connection member 290 have simple structures and are easy to arrange.

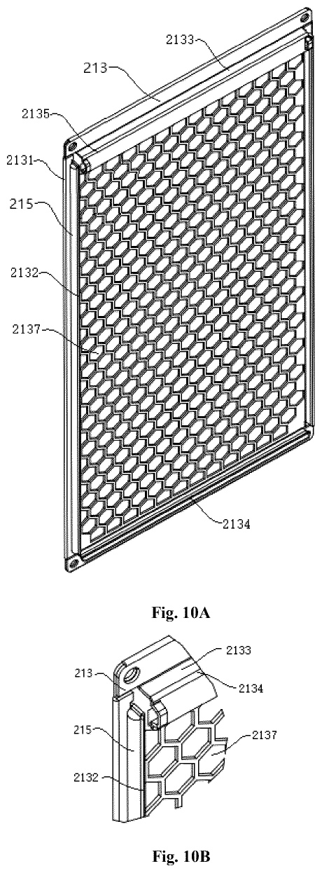

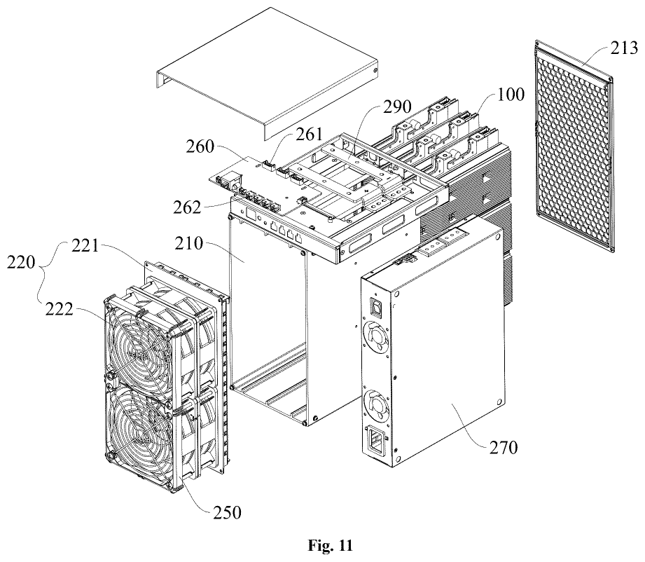

In one implementation, as shown in FIGS. 9A-10B, a ventilation panel 213 is provided on the side of the housing 210 facing away from the fan assembly 220, at least one second elastic component is provided at the edge of the ventilation panel 213, and the second elastic component is pressed tightly between the ventilation panel 213 and the corresponding side wall of the housing 210. Therefore, by providing the above-mentioned second elastic component, the second elastic component may be squeezed into the housing 210, so that the connection between the ventilation panel 213 and the housing 210 is more stable, and the ventilation panel 213 is prevented from falling off from the housing 210.

In one implementation, the ventilation panel 213 includes a ventilation body 2131, a ventilation top plate 2133 and a ventilation bottom plate 2134 that are oppositely disposed, two ventilation side plates 2132, and a second bent portion 2135. A plurality of second ventilation holes 2137 are formed on the ventilation body 2131. The ventilation top plate 2133 and the ventilation bottom plate 2134 are disposed on a side of the ventilation body 2131. The ventilation top plate 2133 is connected to the upper part of the ventilation body 2131, and the ventilation bottom plate 2134 is connected to the lower part of the ventilation body 2131. Two ventilation side plates 2132 are arranged on a side surface of the ventilation body 2131, and the two ventilation side plates 2132 are respectively connected to the two sides of the ventilation body 2131. The second elastic component is disposed on at least one of the two ventilation side plates 2132. The second bent portion 2135 is connected to an end of the ventilation top plate 2133 facing away from the ventilation body 2131, and the second bent portion 2135 is located between the ventilation top plate 2133 and the ventilation bottom plate 2134.

Illustratively, the ventilation bottom plate 2134 and each ventilation side plate 2132 may all be perpendicular to the ventilation body 2131. The ventilation top plate 2133 is connected between the ventilation body 2131 and the second bent portion 2135. After installation, the working assembly 100 may abut against the second bent portion 2135, so that the air flowing through the first heat sink 123 and the second heat sink 124 can better flow into the electronic device 200 or flow out of the electronic device 200 through the second ventilation hole 2137, further improving the heat dissipation effect.

In one example, as shown in FIGS. 9A and 9B, the at least one second elastic component includes a plurality of second elastic clips 214 spaced apart along the second direction, and the second elastic clips 214 are pressed tightly between the ventilation panel 213 and the corresponding side wall of the housing 210.

For example, a plurality of spacing slots 2136 arranged at intervals vertically may be formed on the ventilation side plate 2132, and a portion of the ventilation side plate 2132 between two adjacent spacing slots 2136 is the second elastic clip 214. During installation, the two ventilation side plates 2132 are squeezed into the corresponding side walls of the housing 210. At this time, the plurality of second elastic clips 214 are elastically deformed. Then, the ventilation panel 213 is threadedly connected to the housing 210 via threaded fasteners. During disassembly, only the threaded fasteners need to be removed, and then the ventilation panel 213 is pulled out. At this time, the plurality of second elastic clips 214 return to their original state.

In another example, the above-mentioned at least one second elastic component includes a second conductive foam 215 extending along the second direction. With such a configuration, it is possible that while achieving a firm connection between the ventilation panel 213 and the housing 210, it also allows that the ventilation panel 213 and the housing 210 may be electrically connected via the second conductive foam 215, thereby providing effective shielding and grounding effect, further improving the safety of the electronic device 200.

In one implementation, at least one baffle is disposed on the top of the housing 210, and the baffle corresponds to the heat sink 120 in position. In this way, the air blown out by the fan module 222 may all be blown to a plurality of heat sinks 120, avoiding part of the air from blowing into the top housing 212 on the top of the housing 210, thereby increasing the ventilation volume in the heat-dissipating air duct, avoiding dust accumulation on the heat sink 120, and further improving the heat dissipation effect.

Specifically, the present invention provides an electronic device 200 including:
a housing 210, wherein a heat-dissipating air duct with an air inlet and an air outlet is defined within the housing 210, and at least one working assembly 100 is arranged in the heat-dissipating air duct; and a power supply module 270 configured to supply power to the working assembly 100, wherein the power supply module 270 is disposed on a side surface of the housing 210, and the power supply module 270 is disposed to keep clear of the air inlet and the air outlet.

In the above solution, the housing 210 is generally a cuboid structure, and the housing 210 may include a top surface, a bottom surface, and four side surfaces, and the four side surfaces are respectively connected between the top surface and the bottom surface. The top surface and the bottom surface are opposite to each other in the second direction. The power supply module 270 is arranged flush with one side surface of the housing 210, so that the overall shape and layout of the electronic device 200 are neat. Moreover, the power supply module 270 is disposed to keep clear of the air inlet and the air outlet. The fan assembly 220 may be arranged at one of the air inlet and the air outlet for air conduction and heat exchange, and the other of the air inlet and the air outlet is used for loading and unloading the working assembly 100. The power supply module 270 is arranged on a side surface to facilitate power supply to the fan assembly 220 and the working assembly 100. When a working assembly 100 is damaged, only the damaged working assembly 100 needs to be removed and taken out from the side where the fan assembly 220 is not arranged, without removing the fan assembly 220. The above arrangement facilitates the disassembly and installation of the electronic device 200 as a whole, and also facilitates improving the efficiency of servicing and replacement of the working assembly 100.

Optionally, the housing 210 includes a first housing side surface 216 and a second housing side surface 217 that are disposed opposite to each other, as well as a third housing side surface 218 and a fourth housing side surface 219 that are disposed opposite to each other, the air inlet and the air outlet are respectively disposed on the first housing side surface 216 and the second housing side surface 217, and the power supply module 270 is disposed on the third housing side surface 218 and/or the fourth housing side surface 219.

In the above solution, the first housing side surface 216 and the second housing side surface 217 may be considered as the front side and the rear side of the housing 210, the air inlet may be disposed on the first housing side surface 216 or the second housing side surface 217, and the air outlet may be disposed on the second housing side surface 217 or the first housing side surface 216. For example, in a case where the fan assembly 220 is of the blowing type, the air inlet is disposed on the first housing side surface 216, and the air outlet is disposed on the second housing side surface 217; in a case where the fan assembly 220 is of the suction type, the air inlet is disposed on the second housing side surface 217, and the air outlet is disposed on the first housing side surface 216. The third housing side surface 218 and the fourth housing side surface 219 may be considered as the left side surface and the right side surface of the housing 210, and the power supply module 270 may be disposed on either the left side surface or the right side surface.

It should be noted that the direction “front side surface” may be understood as the side surface on which the fan assembly 220 is disposed; the side opposite thereto is the “rear side surface”, i.e., the side surface facing away from the fan assembly 220. Correspondingly, the two side surfaces connected between the front side surface and the rear side surface are respectively the left side surface and the right side surface.

Optionally, the power supply module 270 comprises a first power supply side surface 274 and a second power supply side surface 275 that are disposed opposite to each other, as well as a third power supply side surface and a fourth power supply side surface 276 that are disposed opposite to each other, wherein the first power supply side surface 274 is coplanar with the first housing side surface 216, the second power supply side surface 275 is coplanar with the second housing side surface 217, and the third power supply side surface is coplanar with the fourth housing side surface 219.

In the above solution, the first power side surface 274 and the second power side surface 275 may be considered as the front side and the rear side of the power supply module 270, and the third power side and the fourth power side surface 276 may be considered as the left side and the right side of the power supply module 270. The front side of the power supply module 270 is coplanar with the front side of the housing 210, the rear side of the power supply module 270 is coplanar with the rear side of the housing 210, and the left side of the power supply module 270 is coplanar with the right side of the housing 270. The power supply module 270 is disposed flush with the housing 210 as a whole, so that the overall shape and layout of the electronic device 200 are regular and it is convenient to disassemble and install the power supply module 270.

Optionally, a top surface of the power supply module 270 is coplanar with a top surface of the housing 210.

In the above solution, a power port is provided at an upper end of the working assembly 100, and a power supply interface is provided at an upper end of the power supply module 270. The top surface of the power supply module 270 is coplanar with the top surface of the housing 210 to facilitate the connection between the power port and the power supply interface. In this way, the overall shape layout of the electronic device 200 is further optimized.

Optionally, a bottom surface of the power supply module 270 is coplanar with a bottom surface of the housing 210.

In the above solution, the arrangement is such that the power supply module 270 is flush with the overall contour of the housing 210, and when the electronic device 200 is placed, the flatness and stability of the bottom surface are ensured.

Optionally, the electronic device 200 further includes: a top housing 212 disposed on the top of the housing 210 and the power supply module 270.

In the above solution, a control board 260 may be arranged within the top housing 212, and the control board 260 may be connected to the working assembly 100, the power supply module 270 and the fan assembly 220. A signal line may be provided between the control board 260 and the working assembly 100, and a power line may be provided between the power supply module 270 and the working assembly 100. The top housing 212 may be used to store the signal line and the power line to avoid cable leakage and protect the internal operating environment of the electronic device 200.

Optionally, the top housing 212 includes a first top housing side surface 2121 and a second top housing side surface 2122 that are disposed opposite to each other, and a third top housing side surface 2123 and a fourth top housing side surface 2124 that are disposed opposite to each other, wherein the first top housing side surface 2121 is coplanar with the air inlet, and the second top housing side surface 2122 is coplanar with the air outlet.

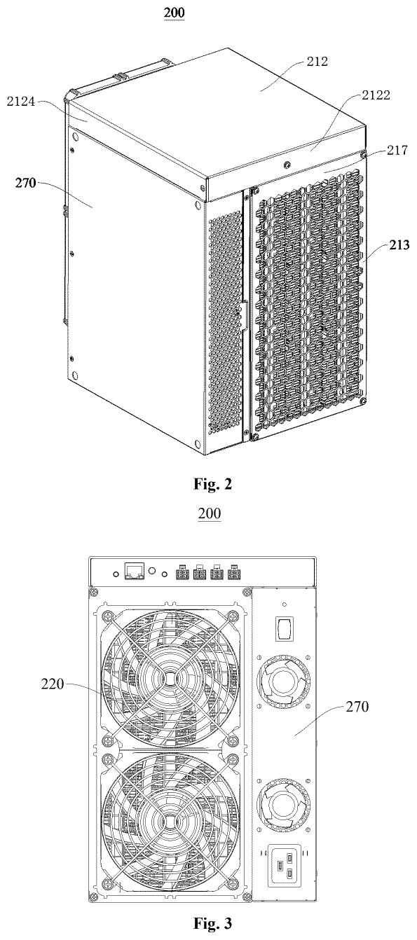

In one example, in combination with FIGS. 1 and 2, the fan assembly 220 may be of the blowing type. In this case, the fan assembly 220 is disposed at the air inlet, the first top housing side surface 2121 is coplanar with the first housing side surface 216, and the second top housing side surface 2122 is coplanar with the second housing side surface 217. Alternatively, in another example, the fan assembly 220 is of the suction type. In this case, the fan assembly 220 is disposed at the air outlet. At this time, the first top housing side surface 2121 is coplanar with the second housing side surface 217, and the second top housing side surface 2122 is coplanar with the first housing side surface 216 (not shown).

In the above solution, the first top housing side surface 2121 and the second top housing side surface 2122 may be considered as the front side surface and the rear side surface of the top housing 212, and the third top housing side surface 2123 and the fourth top housing side surface 2124 may be considered as the left side surface and the right side surface of the top housing 212. The top housing 212 covers the top space of the housing 210 and the power supply module 270, further optimizing the overall shape layout of the electronic device 200. While the power supply module 270 supplies power to the circuit board 110 and the fan assembly 220, the power supply module 270 may effectively utilize the space between the top housing 212 and the housing 210, thereby making the structure of the entire electronic device 200 more compact and the appearance neater and more beautiful.

Optionally, the fourth top housing side surface 2124 is coplanar with a side surface of the power supply module 270, and a side surface of the housing 210 facing away from the power supply module 270 is coplanar with the third top housing side surface 2123.

In the above solution, the left side of the top housing 212 is flush with the left side of the housing 210, and the right side of the top housing 212 is flush with the right side of the power supply module 270, making the structure of the entire electronic device 200 more compact and further optimizing the overall shape layout of the electronic device 200.

It should be supplemented that in the above solution, “coplanar” refers to a situation in comparison to a significant height difference, for example, a height difference between two surfaces of more than 2 cm. The coplanar here may be understood as follows: the two surfaces are in the same plane or the two surfaces have a certain deviation distance, but the visual effect is almost flush. Those skilled in the art will understand that the housing 210 and the power supply module 270, the power supply module 270 and the top housing 212, and the housing 210 and the top housing 212 in the above solution may not be strictly flush due to screws, protective layer structures, reinforcement structures or paint, but as long as faces of corresponding two structures are substantially flush, they all fall within the scope of protection defined by “coplanar” in the present application. In other words, the coplanar mentioned in the present application is to ensure that the outer contours of the electronic device 200 composed of the housing 210, the power supply module 270 and the top housing 212 are substantially flush to the extent of tending to occupy the same plane in geometric mathematics, so as to play a role in optimizing the overall shape layout of the electronic device 200 to facilitate disassembly, installation and use.

Optionally, at least one first positioning portion is disposed on one of the power supply module 270 and the top housing 212, at least one second positioning portion is disposed on the other of the power supply module 270 and the top housing 212, and the first positioning portion mates with the second positioning portion.

In the above solution, the top housing 212 may be positioned and installed with the power supply module 270; more specifically, the top housing 212 may be first connected to the housing 210, and then the power supply module 270 and the top housing 212 may be pre-installed through positioning installation, and finally the power supply module 270 and the housing 210 may be fixedly installed.

Optionally, the first positioning portion is a positioning hole 271, and the second positioning portion is a positioning protrusion, and the positioning protrusion is fitted into the corresponding positioning hole 271. The first positioning portion and the second positioning portion may also be arranged in other forms that can be conceived of in the art.

In the above solution, at least one positioning hole 271 is formed on one of the power supply module 270 and the top housing 212, and at least one positioning protrusion is provided on the other of the power supply module 270 and the top housing 212, and the positioning protrusion is fitted into the corresponding positioning hole 271. More specifically, two positioning holes 271 are formed on the top of the power supply module 270, and the two positioning holes 271 are disposed at intervals along the first direction. Correspondingly, two positioning protrusions disposed at intervals in the first direction may be disposed on the bottom surface of the top housing 212, and the two positioning protrusions correspond one-to-one to the two positioning holes 271.

Optionally, at least one first connection portion is formed on one of the power supply module 270 and the housing 210, and at least one second connection portion corresponding to the first connection portion is formed on the other of the power supply module 270 and the housing 210, and a fastener passes through the first connection portion to be connected to the second connection portion.

In the above solution, after the power supply module 270 and the top housing 212 are pre-installed by positioning and installing, the power supply module 270 and the housing 210 are fastened together by connection and engagement of the first connection portion, the second connection portion and the fastener, and finally the housing 210, the power supply module 270 and the top housing 212 are connected to form the electronic device 200, which facilitates installation and disassembly.

Optionally, the first connection portion is a through hole 272, the second connection portion is a threaded hole, and the fastener is a threaded fastener 273. The first connection portion and the second connection portion may also be arranged in other forms that can be conceived of in the art.

In the above solution, at least one through hole 272 is formed on one of the power supply module 270 and the housing 210, and at least one threaded hole corresponding to the through hole 272 is formed on the other of the power supply module 270 and the housing 210. The threaded fastener 273 is suitable for passing through the through hole 272 and being threadedly connected with the threaded hole. Four through holes 272 are formed on a side surface of the power supply module 270, and the four through holes 272 are respectively located at the four corners of the power supply module 270. Four threaded holes corresponding to the four through holes 272 are formed on the second side surface of the housing 210. During installation, the two positioning protrusions may be respectively fitted into the corresponding positioning holes 271 to achieve positioning of the power supply module 270. Then, four threaded fasteners 273 are respectively passed through the corresponding through holes 272 and threadedly connected with the corresponding threaded holes to fix the power supply module 270.

Optionally, the electronic device also includes: a conductive connection member, one part of which is electrically connected to the power supply module 270, and the other part of which is electrically connected to the working assembly 100.

In the above solution, the conductive connection member is disposed at an upper end of the power supply module 270 and the working assembly 100 to achieve electrical connection between them, and the power supply module 270 supplies power to the working assembly 100.

Optionally, the conductive connection member comprises: a first conductive connection member 280, one part of which is electrically connected to the power supply module 270, and the other part of which is electrically connected to a first connection base 140 of the working assembly 100; and a second conductive connection member 290, one part of which is electrically connected to the power supply module 270, and the other part of which is electrically connected to a second connection base 150 of the working assembly 100.

In the above solution, the bottom surface of the above-mentioned other part of the first conductive connection member 280 may contact the top surfaces of the third connection segments of the three first connection bases 140, and the first fastener is suitable for passing through the first conductive connection member 280 to connect with the third connection segment of the corresponding first connection base 140. The bottom surface of the above-mentioned other part of the second conductive connection member 290 may contact the top surfaces of the third connection segments of the three second connection bases 150, and the second fastener is suitable for passing through the second conductive connection member 290 to connect with the third connection segment of the corresponding second connection base 150. The above-mentioned other portion of the first conductive connection member 280 may be parallel to the above-mentioned other portion of the second conductive connection member 290, and both extend along the third direction. The first conductive connection member 280 may be a positive electrode conductive bar, and the second conductive connection member 290 may be a negative electrode conductive bar.

Optionally, the first connection base 140 and/or the second connection base 150 are provided with an opening for positioning during installation and gas venting during welding.

In the above solution, the first connection base 140 and the second connection base 150 are provided with through holes, and the through holes may be used for welding alignment. In addition, the through holes provided on the first connection base 140 and the second connection base 150 are also conducive to exhausting gas when welding the first connection base 140 and the second connection base 150.

Optionally, the other part of the first conductive connection member 280 and the other part of the second conductive connection member 290 both extend in a direction that is perpendicular to a direction from the air inlet to the air outlet and perpendicular to a vertical direction.

In the above solution, the working assembly 100 is arranged along a third direction, and the above-mentioned other part of the first conductive connection member 280 may be parallel to the above-mentioned other part of the second conductive connection member 290, and both extend along the third direction and are correspondingly connected to the working assembly 100.

Optionally, it further includes: a fan assembly 220 arranged on a side of the housing 210 close to the air inlet.

Optionally, it further includes: a fan assembly 220 arranged on a side of the housing 210 close to the air outlet.

Optionally, the fan assembly 220 includes: a mounting member 221 connected to the housing 210; and a fan module 222 connected to a side of the mounting member 221 facing away from the housing 210.

In the above solution, the fan assembly 220 may be arranged at the air inlet or the air outlet, the outer contour size of the mounting member 221 is larger than the outer contour size of the fan module 222. The mounting member 221 is provided as a transition mounting member at the air inlet or outlet of the housing 210 to facilitate the fixed installation of the fan module 222 on the housing 210. With reference to FIG. 18, a plurality of first ventilation holes 2220 are formed on the portion of the mounting member 221 opposite to the fan module 222. When the fan module 222 is of the blowing type and the fan module 222 is operating, external air enters the heat-dissipating air duct through the plurality of first ventilation holes 2220 under the action of the fan module 222, exchanges heat with the first heat sink 123 and the second heat sink 124, and then flows out from the air outlet. When the fan module 222 is of suction type and the fan module 222 is operating, external air enters the heat-dissipating air duct through the air inlet under the action of the fan module 222, exchanges heat with the first heat 123 and the second heat 124, and then flows out from the plurality of first ventilation holes 2220.

Optionally, the fan assembly 220 includes two fan modules 222 arranged in a vertical direction.

In the above solution, the height of the housing 210 is larger than the length, and there are two fan modules 222 arranged in a vertical direction, and the ventilation area covers the working assembly 100. Of course, for the arrangement of the fan modules 222, other numbers and specifications may be selected based on the size of the housing 210.

Optionally, the two fan modules 222 arranged in the vertical direction constitute a fan group, and a plurality of fan groups are provided in a direction from the air inlet to the air outlet.

In the above solution, in order to increase the heat dissipation effect, a plurality of layers of fan groups are arranged, wherein the preferred solution may arrange one layer of fan groups or two layers of fan groups.

Optionally, first mounting portions are provided at four corners of the fan module 222, second mounting portions are provided on the mounting member 221, and fasteners respectively pass through the first mounting portions to be connected to corresponding second mounting portions.

In the above solution, the fan module 222 and the mounting member 221 may be fastened and connected through corresponding mounting portions, and of course, they may also be connected by bonding. The mounting member 221 may firmly fix the fan module 222 on the housing 210, thereby improving the structural stability and reliability of the entire electronic device 200. The plurality of fan modules 222 can increase the ventilation volume of the heat-dissipating air duct, reduce air resistance, and inhibit the deposition of dust on the heat sink 120, thereby effectively improving the heat dissipation effect of the working assembly 100.

Optionally, the first mounting portions are through holes, the second mounting portions are threaded holes, and the fasteners are threaded fasteners.

In the above solution, the threaded fasteners pass through the through holes of the fan module 222 and are threadedly connected to corresponding threaded holes, thereby achieving a fixed connection between the fan module 222 and the mounting member 221.

A flexible protective cover 250 is provided on a side of the fan module 222 facing away from the mounting member 221. The flexible protective cover 250 is sleeved on an outer periphery of the fan module 222.

In the above solution, the flexible protective cover 250 configured in this way can effectively protecting the edges and corners of the fan module 222, thus preventing the fan module 222 from being worn, and it may prevent the edges and corners of the fan module 222 from scratching workers, thereby improving safety. Optionally, the material of the flexible protective cover 250 may be soft rubber material, but is not limited thereto.

Optionally, the fan assembly 220 and the working assembly 100 are spaced apart from each other in the direction from the air inlet to the air outlet.

In the above solution, there is a certain gap between the mounting member 221 and the working assembly 100 in the first direction. In a case where the fan module 222 is of the blowing type, when the external air enters the heat-dissipating air duct from the fan module 222, it can flow evenly in the gap between the mounting member 221 and the working assembly 100, and then flow through the first heat sink 123 and the second heat sink 124 to improve the heat dissipation effect.

In the description of the present specification, it can be appreciated that orientations or positional relationships indicated by terms such as “central”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential” and the like are orientations or positional relationships based on the drawings, which are only for the convenience of describing the present application and simplifying the description, and do not indicate or imply that the referred device or element must have a specific orientation, be constructed and operated in a specific orientation, and therefore should not be understood as a limitation on the present application.

In addition, terms such as “first” and “second” are used for descriptive purposes only and cannot be understood as indicating or implying relative importance or implicitly indicating the quantity of the indicated technical features. Therefore, a feature defined as “first” or “second” may explicitly or implicitly include one or more of the features.

In the present application, unless otherwise clearly specified and limited, terms such as “mount”, “link”, “connect”, “fix”, etc. and variants thereof should be understood in a broad sense. For example, it may be a fixed connection, or may be a detachable connection, or formed into one piece. It may be a mechanical connection, an electrical connection, or a communication connection. It may be a direct connection or an indirect connection through an intermediate medium. It may be an internal communication between two elements or an interaction relationship between two elements. For those of ordinary skill in the art, the specific meanings of the above terms in the present application may be understood according to specific circumstances.

In the present application, unless otherwise clearly specified and limited, a first feature being “on” or “under” a second feature may include the first and second features being in direct contact, or may include the first and second features not being in direct contact but being in contact through another feature between them. Moreover, a first feature being “over”, “above”, or “onto” a second feature includes the first feature being directly above or obliquely above the second feature, or simply means that the first feature is at a higher horizontal level than the second feature. A first feature being “under”, “below”, or “beneath” a second feature includes the first feature being directly below or diagonally below the second feature, or simply means that the first feature is at a lower horizontal level than the second feature.

The above disclosure provides many different embodiments or examples for implementing different structures of the present application. In order to simplify the disclosure of the present application, components and arrangements of specific examples are described above. Of course, they are merely examples and are not intended to limit the present application. In addition, the present application may repeat reference numerals and/or reference letters in different examples. Such repetition is for the purpose of simplicity and clarity, which is not aimed to indicate relationships between various embodiments and/or arrangements discussed.

The above are only detailed description of the present application, the protection scope of the present application is not limited thereto. Any technician familiar with the technical field may easily conceive of various changes or substitutions within the technical scope disclosed in the present application, which should all be encompassed in the protection scope of the present application. Therefore, the protection scope of the present application should be based on the protection scope of the claims.

1. An electronic device, comprising:
a housing, wherein a heat-dissipating air duct with an air inlet and an air outlet is defined within the housing, and at least one working assembly is disposed in the heat-dissipating air duct; and
a power supply module configured to supply power to the working assembly, wherein the power supply module is disposed on a side surface of the housing, and the power supply module is disposed to keep clear of the air inlet and the air outlet.

2. The electronic device as claimed in claim 1, wherein the housing comprises a first housing side surface and a second housing side surface that are disposed opposite to each other, as well as a third housing side surface and a fourth housing side surface that are disposed opposite to each other, the air inlet and the air outlet are disposed on the first housing side surface and the second housing side surface, respectively, and the power supply module is disposed on the third housing side surface and/or the fourth housing side surface.

3. The electronic device as claimed in claim 2, wherein the power supply module comprises a first power supply side surface and a second power supply side surface that are disposed opposite to each other, as well as a third power supply side surface and a fourth power supply side surface that are disposed opposite to each other, wherein the first power supply side surface is coplanar with the first housing side surface, the second power supply side surface is coplanar with the second housing side surface, and the third power supply side surface is coplanar with the fourth housing side surface.

4. The electronic device as claimed in claim 1, wherein a top surface of the power supply module is coplanar with a top surface of the housing; and
wherein a bottom surface of the power supply module is coplanar with a bottom surface of the housing.

5. (canceled)

6. The electronic device as claimed in claim 1, further comprising:
a top housing disposed on the top of the housing and the power supply module.

7. The electronic device as claimed in claim 6, wherein the top housing comprises a first top housing side surface and a second top housing side surface that are disposed opposite to each other, as well as a third top housing side surface and a fourth top housing side surface that are disposed opposite to each other, wherein the first top housing side surface is coplanar with the air inlet, and the second top housing side surface is coplanar with the air outlet.

8. The electronic device as claimed in claim 7, wherein the fourth top housing side surface is coplanar with a side surface of the power supply module, and a side surface of the housing facing away from the power supply module is coplanar with the third top housing side surface.

9. The electronic device as claimed in claim 6, wherein at least one first positioning portion is provided on one of the power supply module and the top housing, at least one second positioning portion is provided on the other of the power supply module and the top housing, and the first positioning portion mates with the second positioning portion;
wherein the first positioning portion is a positioning hole, the second positioning portion is a positioning protrusion, and the positioning protrusion is fitted into a corresponding positioning hole.

10. (canceled)

11. The electronic device as claimed in claim 1, wherein at least one first connection portion is formed on one of the power supply module and the housing, at least one second connection portion corresponding to the first connection portion is formed on the other of the power supply module and the housing, and a fastener passes through the first connection portion to be connected to the second connection portion;
wherein the first connection portion is a through hole, the second connection portion is a threaded hole, and the fastener is a threaded fastener.

12. (canceled)

13. The electronic device as claimed in claim 1, further comprising:
a conductive connection member, one part of which is electrically connected to the power supply module, and the other part of the conductive connection member is electrically connected to the working assembly.

14. The electronic device as claimed in claim 13, wherein the conductive connection member comprises:
a first conductive connection member, one part of which is electrically connected to the power supply module, and the other part of the first conductive connection member is electrically connected to a first connection base of the working assembly; and
a second conductive connection member, one part of which is electrically connected to the power supply module, and the other part of the second conductive connection member is electrically connected to a second connection base of the working assembly.

15. The electronic device as claimed in claim 14, wherein the first connection base and/or the second connection base is provided with an opening for positioning during installation and gas venting during welding.

16. The electronic device as claimed in claim 14, wherein the other part of the first conductive connection member and the other part of the second conductive connection member both extend in a direction that is perpendicular to a direction from the air inlet to the air outlet and perpendicular to a vertical direction.

17. The electronic device as claimed in claim 1, further comprising:
a fan assembly arranged on a side of the housing close to the air inlet.

18. The electronic device as claimed in claim 1, further comprising:
a fan assembly arranged on a side of the housing close to the air outlet.

19. The electronic device as claimed in claim 1, further comprising a fan assembly;
wherein the fan assembly comprises:
a mounting member connected to the housing; and
a fan module connected to a side of the mounting member facing away from the housing.

20. The electronic device as claimed in claim 19, wherein the fan assembly comprises two fan modules arranged in a vertical direction;
wherein the two fan modules arranged in the vertical direction constitute a fan group, and there are a plurality of fan groups disposed in a direction from the air inlet to the air outlet.

21. (canceled)

22. The electronic device as claimed in claim 19, wherein first mounting portions are provided at four corners of the fan module, second mounting portions are provided on the mounting member, and fasteners respectively pass through the first mounting portions to be connected to corresponding second mounting portions;
wherein the first mounting portions are through holes, the second mounting portions are threaded holes, and the fasteners are threaded fasteners.

23. (canceled)

24. The electronic device as claimed in claim 19, wherein a flexible protective cover is provided on a side of the fan module facing away from the mounting member, and the flexible protective cover is sleeved on an outer periphery of the fan module.

25. The electronic device as claimed in claim 19, wherein the fan assembly and the working assembly are disposed to be spaced apart from each other in a direction from the air inlet to the air outlet.
